(19) United States
(12) Patent Application Publication
(10) Pub. No.: US 2014/0202749 A1
(43) Pub. Date: Jul. 24, 2014

(54) RESIN COMPOSITION FOR FORMING INK-RECEIVING LAYER AND INK-RECEIVING BASE, PRINTED MATTER AND CONDUCTIVE PATTERN PRODUCED BY USING THE RESIN COMPOSITION

(71) Applicants: Yukie Saitou, Osaka (JP); Wataru Fujikawa, Osaka (JP); Jun Shirakami, Osaka (JP)

(72) Inventors: Yukie Saitou, Osaka (JP); Wataru Fujikawa, Osaka (JP); Jun Shirakami, Osaka (JP)

(73) Assignee: DIC CORPORATION, Tokyo (JP)

(21) Appl. No.: 14/237,004

(22) PCT Filed: Jul. 4, 2012
(86) PCT No.: PCT/JP2012/067063

§ 371 Date: Feb. 4, 2014

(30) Foreign Application Priority Data
Aug. 4, 2011 (JP) 2011-170996

(51) Int. Cl. H05K 1/09; H05K 3/12; C09D 133/12

(52) U.S. Cl. CPC H05K 1/092; C09D 133/12; H05K 3/1283
USPC 174/257; 524/558; 524/561; 524/502; 428/195.1; 427/97.5

(57) ABSTRACT

An object of the present invention is to provide a resin composition for forming an ink-receiving layer that is capable of forming a printed image having excellent printing properties and water resistance, both in the case of use of a water-based ink and in the case of use of a solvent-based ink. The resin composition for forming an ink-receiving layer includes a binder resin (A) having a weight-average molecular weight of 100,000 or more and an acid value of 90 to 450, an aqueous medium (B), and as required, at least one component (C) selected from the group consisting of a water-soluble resin (c1) and an inorganic filler (c2). The binder resin (A) is dispersed in the aqueous medium (B), and the content of the at least one component (C) relative to the total amount of the binder resin (A) is 0% to 15% by mass.

### TECHNICAL FIELD

The present invention relates to a resin composition for forming an ink-receiving layer that can receive an ink, for example, ejected by a method such as an ink-jet printing method, an ink-receiving base, and printed matter such as a conductive pattern.

### BACKGROUND ART

Recently, in the ink-jet printing-related industry, which has been significantly growing, there have been significant advances in the realization of high-performance ink-jet printers, improvement of inks, and the like, and images having high definition and sharpness, which are substantially equivalent to silver halide prints, have been easily obtained even in ordinary households. Therefore, ink-jet printers are not only used in homes but have also started to be considered for use in the production of large advertisement boards or the like.

The realization of high quality of ink-jet printed matter is mainly due to the improvement in printing inks in addition to the realization of high performance of the printers. Specific examples of the improvement in printing inks include studies on the selection of solvents in inks and the selection of dyes or pigments in inks. In recent years, pigment inks, which are known as inks having a good color-developing property equivalent to that of dye inks, have attracted attention.

Among the pigment inks, water-based inks are produced by dispersing a pigment or the like in an aqueous medium. Such water-based inks can usually form, for example, printed images in which discoloration and the generation of cracks do not easily occur during printing.

As for an ink-receiving layer developed for such water-based inks, for example, a known ink-jet recording medium includes an ink-receiving layer formed by using an aqueous resin composition that contains a water-soluble resin, a water-dispersible resin, a compound having two or more silyl groups and two or more secondary amino groups in one molecule, and water (refer to, for example, PTL 1). In general, such an ink-receiving layer contains a water-soluble resin such as polyvinyl alcohol in an amount of about 50% by mass so that even when a large amount of ink is applied onto a surface of a base as in the case where an industrial ink-jet printer is used, for example, the ink-receiving layer can sufficiently absorb a solvent in the ink and, as a result, a highly sharp image is formed without causing bleeding or the like.

However, the water-soluble resin such as polyvinyl alcohol may increase the hydrophilicity of the ink-receiving layer and significantly decrease the water resistance of the ink-receiving layer. Therefore, when rainwater or the like adheres to a surface of the ink-receiving layer, dissolution or swelling may be caused, resulting in bleeding and discoloration of a printed image formed by using a water-based ink, for example. Thus, the ink-receiving layer may have insufficient water resistance.

Besides the water-based inks described above, solvent-based inks that do not easily cause discoloration, bleeding, and generation of cracks of printed images and that can form printed images having high sharpness and a good color-developing property are also known as the pigment inks.

However, the high-quality printed images cannot be easily obtained even if the solvent-based inks are simply used instead of the water-based inks. It is necessary to use an ink-receiving base including an ink-receiving layer that is suitable for the solvent-based inks.

Specifically, existing ink-receiving layers developed for water-based inks are designed for the purpose of improving absorbency of an aqueous medium in a water-based ink and improving a fixing property of a dye or a pigment in the ink. Therefore, according to technical common knowledge, even when printing is performed on an existing ink-receiving layer developed for a water-based ink using the above-described solvent-based ink, the ink-receiving layer cannot absorb a solvent with high efficiency, and, as a result, it is difficult to obtain an image which has a good color-developing property and in which bleeding and discoloration are prevented.

For example, a known ink-receiving layer developed for the water-based ink is a generally called microporous ink-receiving layer that contains an inorganic filler such as silica in an amount of about 50% by mass. Such an ink-receiving layer can also sufficiently absorb a solvent contained in an ink, and thus can be suitable for use as a receiving layer for a water-based ink.

However, even when printing is performed on the microporous ink-receiving layer using a solvent-based ink, there may be a problem in that the absorbency of the ink is not good and bleeding occurs.

As described above, it is necessary to change the ink-receiving layer in each case in accordance with the type of ink used in printing. Thus, the production efficiency of printed matter may be significantly decreased.

Accordingly, in the industry, there is a desire for the development of a resin composition capable of forming an ink-receiving layer that can combine excellent water resistance and excellent printing properties regardless of the type of the solvent of an ink, that is, in both the case where printing is performed using a water-based ink and the case where printing is performed using a solvent-based ink.

In recent years, with an increase in the requirements of realization of high performance, reduction in the size, and reduction in the thickness of electronic devices, realization of an increase in the integration density and a reduction in the thickness are also strongly desired for electronic circuits and integrated circuits used in the electronic devices.

Conductive patterns used in the electronic circuits etc. have been hitherto formed by a photolithography method. However, a large number of steps need to be performed in this method, which may decrease the production efficiency of the conductive patterns. Therefore, simplification etc. of the method have been studied.

With a remarkable improvement of the ink-jet printing techniques described above, improvements in ink-jet printers and inks have advanced. A technique for forming a conductive pattern of an electronic circuit or the like has been developed in which a conductive ink containing a conductive substance such as silver is printed on a substrate by an ink-jet printing method.

However, even when the conductive ink is printed directly on a surface of a substrate composed of polyimide, polyethylene terephthalate, or the like which is generally used in an electronic circuit or the like, the conductive ink does not easily adhere to the surface of the substrate and thus is easily separated from the surface. This separation of the conductive ink may cause disconnection of an electronic circuit or the like that is finally obtained and interruption of supply of electricity.

An example of a known method for solving the above problem is a method for forming a conductive pattern by drawing a pattern on an ink-receiving base including a latex layer thereon using a conductive ink by a particular method. It is known that an acrylic resin can be used as the latex layer (refer to, for example, PTL 2).

However, an ink-receiving layer formed of the latex layer on which the conductive pattern is formed may cause, for example, bleeding of the conductive ink. Therefore, it may be difficult to form a conductor line formed of a thin line having a width of about 0.01 to 200 μm, which is generally required for achieving, for example, an increase in the integration density of an electronic circuit or the like.

Furthermore, in the formation of the conductive pattern, in general, printed matter obtained by performing printing using a conductive ink is baked by being heated at a temperature of about 80° C. or higher in order to provide electrical conductivity by brining conductive substances contained in the conductive ink into contact with each other.

However, an ink-receiving layer such as the latex layer described in PTL 2 is, for example, easily degraded by the influence of heat received in the baking step, resulting in a decrease in the adhesiveness at an interface between the ink-receiving layer and the substrate. Consequently, even when a very small force is applied, the ink-receiving layer may be easily separated. In addition, excessive swelling, deformation, etc. of the latex layer functioning as an ink-receiving layer may be caused through the baking step, which may result in disconnection and failure of electrical conduction.

In the formation of the conductive pattern, a plating process is often performed on the surface of the conductive pattern for the purpose of further improving electrical conductivity.

However, chemical agents for plating used in the plating process and chemical agents used in a washing step of the plating process are usually strong alkali or strong acidic, and thus the chemical agents causes, for example, dissolution of the conductive pattern, the conductive ink-receiving layer, etc. As a result, disconnection or the like may occur.

Accordingly, the conductive pattern requires durability of such a level that dissolution or the like of the conductive ink-receiving layer is not caused even when the conductive pattern is repeatedly immersed in the chemical agent etc. for a long time.

### CITATION LIST

### Patent Literature

PTL 1: Japanese Unexamined Patent Application Publication No. 2006-96797

PTL 2: Japanese Unexamined Patent Application Publication No. 2009-49124

### SUMMARY OF INVENTION

### Technical Problem

A first object to be achieved by the present invention is to provide a resin composition for forming an ink-receiving layer capable of forming a printed image having excellent printing properties and excellent water resistance without causing bleeding, cracks, etc. in both the case where printing is performed using water-based ink and the case where printing is performed using the solvent-based ink.

A second object to be achieved by the present invention is to provide a resin composition for forming an ink-receiving layer capable of forming a conductive pattern having adhesiveness to various types of substrates and a fine-line-forming property of drawing a fine line at such a level that, for example, an increase in the integration density of electronic circuits or the like is achieved in both the case where printing is performed using a water-based ink containing a conductive substance and the case where printing is performed using a solvent-based ink containing a conductive substance.

A third object to be achieved by the present invention is to provide a resin composition for forming a conductive ink-receiving layer capable of forming printed matter having durability of such a level that a good electrical conduction property can be maintained without causing, for example, dissolution and separation of the ink-receiving layer even in the case where chemical agents for plating and solvents used as a washing agent adhere to the printed matter.

### Solution to Problem

In the improvement of the water resistance of printed images or the like formed by using a water-based ink, the inventors of the present invention conducted studies on the basis of an existing so-called swelling-type ink-receiving layer. Specifically, the inventors of the present invention conducted studies on the assumption that, in order to improve the water resistance, it is important to minimize the use of a water-soluble resin such as polyvinyl alcohol contained in the existing swelling-type ink-receiving layer.

However, as known as technical common knowledge, when the amount of water-soluble resin such as polyvinyl alcohol, which can be usually contained in the swelling-type ink-receiving layer for a water-based ink, is reduced, it becomes difficult to receive a water-based ink. As expected, when the amount of the water-soluble resin used was simply reduced, bleeding, cracks, etc. of printed images formed by using a water-based ink occurred and it was difficult to provide excellent printing properties.

Therefore, the inventors of the present invention conducted studies on the assumption that the reduction in the amount of the water-soluble resin used can be compensated for by setting the acid value of a vinyl resin contained in the resin composition for forming an ink-receiving layer to be slightly higher than that of an existing resin.

By setting the acid value of the resin composition for forming an ink-receiving layer to be slightly higher than those of existing resin compositions, bleeding, cracks, etc. of printed images formed by using a water-based ink were somewhat improved. However, it was still difficult to provide sufficiently high printing properties and water resistance.

Furthermore, the inventors of the present invention conducted studies in which the acid value was further increased. However, when the acid value was excessively high, bleeding, cracks, etc. of printed images tended to be caused in the case where a solvent-based ink was used, resulting in a problem of a significant decrease in printing properties.

Consequently, various studies were conducted on the basis of a resin composition for forming an ink-receiving layer, the resin composition containing a vinyl resin having such a high acid value. As a result, it was found that when a resin composition for forming an ink-receiving layer contains a vinyl resin that has a high acid value and a high molecular weight, it is possible to form a printed image having excellent printing properties and excellent water resistance in which bleeding, cracks, etc. are not caused in both the case where printing is performed using a water-based ink and the case where printing is performed using a solvent-based ink, and to form an ink-receiving layer having excellent adhesiveness with a substrate. It was found that, with the above resin composition for forming an ink-receiving layer, in particular, a large amount of an ink solvent can be sufficiently absorbed and a printed image having excellent water resistance etc. can be formed even in the case where an industrial ink-jet printer or the like is used.

In addition, the inventors of the present invention found that it is possible to form an ink-receiving layer capable of forming a conductive pattern having adhesiveness to various types of substrates and a fine-line-forming property of drawing a fine line at such a level that the fine line can be practically used in the technical fields of electronic circuits etc. in both the case where printing is performed using a water-based ink containing a conductive substance and the case where printing is performed using a solvent-based ink containing a conductive substance.

The inventors of the present invention further conducted studies and found that, by performing printing on an ink-receiving base using an ink and then forming a cross-linked structure in the resulting ink-receiving layer by heating or the like, it is possible to form printed matter having high durability of such a level that a good electrical conduction property can be maintained without causing dissolution, separation, etc. of the ink-receiving layer even when chemical agents for plating and solvents such as a washing agent adhere to the ink-receiving base.

Specifically, the present invention relates to a resin composition for forming an ink-receiving layer, the resin composition including a binder resin (A) having a weight-average molecular weight of 100,000 or more and an acid value of 90 to 450, an aqueous medium (B), and as required, at least one component (C) selected from the group consisting of a water-soluble resin (c1) and an inorganic filler (c2). The binder resin (A) is dispersed in the aqueous medium (B), and the content of the at least one component (C) relative to the total amount of the binder resin (A) is 0% to 15% by mass. The present invention also relates to an ink-receiving base and printed matter.

The present invention relates to a conductive pattern and an electric circuit which are each produced by performing printing, with the conductive ink, on the ink-receiving layer of the ink-receiving base.

The present invention relates to a method for producing printed matter, the method including applying the resin composition for forming an ink-receiving layer onto part or the entirety of a surface of a substrate, forming a substantially uncross-linked ink-receiving layer by performing drying under a condition in which the resin composition for forming an ink-receiving layer does not undergo a cross-linking reaction, then performing printing on a surface of the ink-receiving layer with an ink, and then forming a cross-linked structure by heating the ink-receiving layer on which the printing has been performed.

### Advantageous Effects of Invention

According to the resin composition for forming an ink-receiving layer according to the present invention, it is possible to form an ink-receiving layer that can combine both excellent water resistance and excellent printing properties in both the case where printing is performed using a water-based ink and the case where printing is performed using a solvent-based ink. Accordingly, the resin composition for forming an ink-receiving layer according to the present invention can be used in, for example, an ink-jet recording medium used for producing an advertisement, a signboard, a sign, etc. that can be installed indoors or outdoors.

Furthermore, according to the resin composition for forming an ink-receiving layer according to the present invention, it is possible to form an ink-receiving layer having excellent adhesiveness between the ink-receiving layer and a substrate, and it is possible to form a conductive ink-receiving layer having a fine-line-forming property of drawing a fine line without causing bleeding of a conductive ink at such a level that, for example, an increase in the integration density of electronic circuits or the like can be achieved. Accordingly, the resin composition for forming an ink-receiving layer can be generally used in new fields such as a printed electronics field, for example, in the formation of an electronic circuit using, for example, a conductive ink containing a conductive substance such as silver, the formation of layers and peripheral wiring that are included in an organic solar cell, an electronic book terminal, an organic electroluminescence (EL) device, an organic transistor, a flexible printed circuit board, radio-frequency identification (RFID) such as a non-contact IC card, etc., and the production of wiring of an electromagnetic wave shield, an integrated circuit, an organic transistor of a plasma display, etc.

In addition, by performing printing on the ink-receiving base according to the present invention using an ink and then forming a cross-linked structure in the resulting ink-receiving layer by heating or the like, it is possible to obtain printed matter having durability of such a level that, for example, detachment of a pigment, a conductive substance, etc. contained in the ink can be prevented.

### DESCRIPTION OF EMBODIMENTS

A resin composition for forming an ink-receiving layer according to the present invention contains a binder resin (A) having a weight-average molecular weight of 100,000 or more and an acid value of 90 to 450, an aqueous medium (B), and as required, at least one component (C) selected from the group consisting of a water-soluble resin (c1) and an inorganic filler (c2). The binder resin (A) is dispersed in the aqueous medium (B), and the content of the at least one component (C) relative to the total amount of the binder resin (A) is 0% to 15% by mass.

In the present invention, a binder resin that satisfies all the conditions of (1) a weight-average molecular weight of 100,000 or more and (2) a relatively high acid value of 90 to 450 is used as the binder resin (A), preferably as a vinyl resin (A1) without simply using a binder resin having an acid group. This is important for forming an ink-receiving layer having excellent printing properties, excellent water resistance, etc. in both the case where printing is performed using a water-based ink and the case where printing is performed using a solvent-based ink.

If a resin composition for forming an ink-receiving layer containing, instead of the binder resin (A), a binder resin that satisfies the condition (1) but has an acid value of 75 is used, in particular, printing properties of a printed image formed by using a water-based ink tend to degrade.

If a resin composition for forming an ink-receiving layer containing, instead of the binder resin (A), a binder resin that satisfies the condition (1) but has an acid value of 480 is used, in particular, printing properties and water resistance of a printed image formed by using a solvent-based ink tend to significantly degrade. Furthermore, when this resin composition for forming an ink-receiving layer is used in producing a conductive pattern, a fine-line-forming property may be degraded.

If a resin composition for forming an ink-receiving layer containing, instead of the binder resin (A), a binder resin that satisfies the condition (2) but has a weight-average molecular weight of 90,000 is used, in particular, printing properties of a printed image formed by using a solvent-based ink may significantly degrade. Furthermore, when this resin composition for forming an ink-receiving layer is used in producing a conductive pattern, a fine-line-forming property may be degraded.

The binder resin (A) used preferably has an acid value of 100 to 400, more preferably 100 to 300, and particularly preferably 100 to 280. In particular, when the resin composition for forming an ink-receiving layer according to the present invention is used in the formation of a conductive pattern, a binder resin having an acid value of 100 to 300 is preferably used and a binder resin having an acid value of 100 to 280 is particularly preferably used from the standpoint of providing an excellent fine-line-forming property and excellent adhesiveness to a substrate.

The acid value of the binder resin (A) is derived from a cross-linkable functional group described below and a hydrophilic group such as an anionic group that can be introduced for the purpose of providing good water dispersibility to the binder resin (A). Specifically, the acid value is preferably derived from an anionic group such as a carboxyl group or a sulfonic acid group, or a carboxylate group or a sulfonate group which is a neutralized product thereof. The acid value is more preferably derived from a carboxyl group or a carboxylate group.

Some or all of the carboxyl groups or sulfonic acid groups may be neutralized with a basic compound such as a basic metal compound, e.g., potassium hydroxide, or a basic nonmetal compound, e.g., ammonia to form a carboxylate group. However, the carboxyl groups or the sulfonic acid groups are not necessarily neutralized.

The binder resin (A) may have the carboxyl group or the like in an amount in which good water dispersibility and a good cross-linking property are considered. However, the binder resin (A) preferably has the carboxyl group or the like in an amount in which the acid value derived from the carboxyl group or the like is in the range described above.

It is not sufficient that the binder resin (A) simply have an acid value in the above range. From the standpoint that a printed image having excellent printing properties and excellent water resistance is formed in both the case where a water-based ink is used and the case where a solvent-based ink is used, it is essential to use a binder resin having a weight-average molecular weight of 100,000 or more, and it is preferable to use a binder resin having a weight-average molecular weight of 1,000,000 or more.

The upper limit of the weight-average molecular weight of the binder resin (A) is not particularly limited, but is preferably about 10,000,000 or less and more preferably 5,000,000 or less. From the standpoint of forming a conducting ink-receiving layer in which bleeding does not occur in the formation of a conductive pattern or the like and which has an excellent fine-line-forming property, the binder resin (A) having a weight-average molecular weight in the above range is preferably used.

The weight-average molecular weight of the binder resin (A) can be usually measured by gel permeation chromatography (GPC) using a measurement sample prepared by mixing 80 mg of the binder resin (A) and 20 mL of tetrahydrofuran, and stirring the resulting mixed solution for 12 hours. A high-performance liquid chromatograph HLC-8220 manufactured by Tosoh Corporation can be used as a measuring apparatus. TSKgel GMH XL×4 column manufactured by Tosoh Corporation can be used as a column. Tetrahydrofuran can be used as an eluent. An RI detector can be used as a detector.

However, in the case where the molecular weight of the binder resin (A) exceeds about 1,000,000, it may be difficult to measure the molecular weight of the binder resin (A) by a typical molecular weight measuring method that uses GPC or the like.

Specifically, even after 80 mg of a binder resin (A) having a weight-average molecular weight of more than 1,000,000 is mixed with 20 mL of tetrahydrofuran and the resulting mixed solution is stirred for 12 hours, the binder resin (A) may not be completely dissolved. In such a case, when the mixed solution is filtered using a 1-μm membrane filter, a residue composed of the binder resin (A) may be confirmed on the membrane filter.

Such a residue is derived from a binder resin having a molecular weight of about more than 1,000,000. Accordingly, even if the molecular weight is measured by GPC using a filtrate obtained by the filtration, it may be difficult to measure an accurate weight-average molecular weight of the binder resin.

In the present invention, when a residue is confirmed on the membrane filter as a result of the filtration, such a resin is determined to be a vinyl resin having a weight-average molecular weight of more than 1,000,000.

The binder resin (A) can be dispersed in an aqueous medium (B) described below. A part of the binder resin (A) may be dissolved in the aqueous medium (B).

Various resins such as a vinyl resin (A1), a urethane resin, and an olefin resin can be used as the binder resin (A). From the standpoint of solving the above problems, a vinyl resin (A1) is particularly preferably used.

The binder resin (A), preferably the vinyl resin (A1), may have a functional group, as required.

Examples of the functional group include cross-linkable functional groups such as an amide group, a hydroxyl group, a glycidyl group, an amino group, a silyl group, an aziridinyl group, an isocyanate group, an oxazoline group, a cyclopentenyl group, an allyl group, a carboxyl group, and an acetoacetyl group.

When printing is performed on the ink-receiving base using an ink and heating or the like is then performed, the cross-linkable functional group undergoes a cross-linking reaction to form a cross-linked structure. Consequently, it is possible to form printed matter such as a conductive pattern having high durability at such a level that a good electrical conduction property can be maintained without causing dissolution, separation, etc. of an ink-receiving layer even when, for example, a chemical agent for plating or a solvent such as a washing agent adheres to the ink-receiving base.

For example, a cross-linkable functional group that can undergo a cross-linking reaction by being heated to about 100° C. or higher to form the cross-linked structure is preferably used as the cross-linkable functional group. Specifically, at least one thermally cross-linkable functional group selected from the group consisting of a methylolamide group and alkoxymethylamide groups is preferably used.

Specific examples of the alkoxymethylamide group include amide groups in which a methoxymethyl group, an ethoxymethyl group, a propoxymethyl group, a butoxymethyl group, or the like is bonded to a nitrogen atom.

In the case where a cross-linking agent (D) described below is used, for example, a hydroxyl group, a carboxyl group, or the like is preferably used as the cross-linkable functional group. In the case where the conditions for forming the ink-receiving layer can be sufficiently controlled, an amino group can also be used.

The binder resin (A), preferably the vinyl resin (A1), preferably has a glass transition temperature of 1° C. to 70° C. from the standpoint of providing, to a printed image, excellent printing properties in which bleeding, cracks, etc. are not generated and producing a conductive pattern, and particularly providing an excellent fine-line-forming property in both the case where a water-based ink is used and the case where a solvent-based ink is used.

In addition, a binder resin, preferably a vinyl resin, having a glass transition temperature of 10° C. to 40° C. is preferably used from the standpoint of providing a good film-forming property in the formation of an ink-receiving layer, and providing blocking resistance at such a level that adhesion with time between an ink-receiving layer, which is formed on an ink-receiving base, and a back surface of a substrate, which constitutes the ink-receiving base, does not occur when the ink-receiving base is wound around a roll or the like or when ink-receiving bases are stacked.

The vinyl resin (A1) can be produced by polymerizing a vinyl monomer mixture containing a vinyl monomer having an acid group such as a carboxyl group and other optional vinyl monomers.

Examples of the vinyl monomer that has an acid group and that can be used in the production of the vinyl resin (A1) include vinyl monomers having a carboxyl group, such as acrylic acid, methacrylic acid, β-carboxyethyl (meth)acrylate, 2-(meth)acryloyl propionic acid, crotonic acid, itaconic acid, maleic acid, fumaric acid, itaconic acid half-ester, maleic acid half-ester, maleic anhydride, and itaconic anhydride; vinyl sulfonic acid, styrene sulfonic acid, and salts thereof; sulfonic acids having an allyl group and salts thereof, such as allyl sulfonic acid and 2-methylallyl sulfonic acid; sulfonic acids having a (meth)acrylate group and salts thereof, such as 2-sulfoethyl (meth)acrylate and 2-sulfopropyl (meth)acrylate; sulfonic acids having a (meth)acrylamide group and salts thereof, such as (meth)acrylamide-t-butylsulfonic acid; and “ADEKA REASOAP PP-70 and PPE-710” (manufactured by ADEKA Corporation) having a phosphate group. The vinyl monomers having a carboxyl group and salts thereof are preferably used.

The vinyl monomer having an acid group can be used in such a range that the acid value of the vinyl resin (A1), which is finally obtained, is adjusted to 90 to 450. Specifically, the content of the vinyl monomer having an acid group is preferably in the range of 6% to 70% by mass, more preferably in the range of 10% to 60% by mass, and still more preferably in the range of 15% to 50% by mass relative to the total amount of the vinyl monomer mixture. By using a predetermined amount of vinyl monomer having an acid group, good water dispersion stability etc. can be provided to the resulting vinyl resin (A1).

In the case where the resin composition for forming an ink-receiving layer according to the present invention is used in the formation of a conductive pattern, the vinyl monomer having an acid group is preferably used in such a range that the acid value is adjusted to 100 to 300, and the content of the vinyl monomer having an acid group is preferably in the range of 10% to 60% by mass, and more preferably in the range of 15% to 50% by mass from the standpoint of providing an excellent fine-line-forming property and excellent adhesiveness to a substrate.

In the vinyl monomer mixture that can be used in the production of the vinyl resin (A1), other vinyl monomers are preferably used in combination in addition to, for example, the vinyl monomer having an acid group.

Examples of the other vinyl monomers that can be used include (meth)acrylic acid esters such as methyl (meth)acrylate, ethyl (meth)acrylate, n-butyl (meth)acrylate, i-butyl (meth)acrylate, t-butyl (meth)acrylate, 2-ethylhexyl (meth)acrylate, hexyl (meth)acrylate, cyclohexyl (meth)acrylate, octyl (meth)acrylate, nonyl (meth)acrylate, dodecyl (meth)acrylate, stearyl (meth)acrylate, isobornyl (meth)acrylate, dicyclopentanyl (meth)acrylate, phenyl (meth)acrylate, and benzyl (meth)acrylate; and (meth)acrylic acid alkyl esters such as 2,2,2-trifluoroethyl (meth)acrylate, 2,2,3,3-pentafluoropropyl (meth)acrylate, perfluorocyclohexyl (meth)acrylate, 2,2,3,3-tetrafluoropropyl (meth)acrylate, and β-(perfluorooctyl)ethyl (meth)acrylate.

Among these, methyl (meth)acrylate is preferably used. Methyl methacrylate is preferably used because excellent printing properties etc. can be provided in both the case where a water-based ink is used and the case where a solvent-based ink is used, and in particular, excellent printing properties can be provided when a printed image is formed using a solvent-based ink. In addition, the use of methyl methacrylate is preferable because it is possible to form a conductive ink-receiving layer having a fine-line-forming property at such a level that a fine line having a width of about 0.01 to 200 μm and preferably about 0.01 to 150 μm, which is required for forming a conductive pattern of an electronic circuit or the like, can be printed without causing bleeding even in the case where the conductive pattern is formed using a conductive ink or the like.

The content of the methyl (meth)acrylate is preferably in the range of 0.01% to 80% by mass, more preferably in the range of 0.1% to 50% by mass, still more preferably in the range of 0.5% to 30% by mass, and particularly preferably in the range of 1% to 20% by mass relative to the total amount of the vinyl monomer mixture.

A (meth)acrylic acid alkyl ester having an alkyl group having 2 to 12 carbon atoms is preferably used as the (meth)acrylic acid alkyl ester in combination with the methyl (meth)acrylate. An acrylic acid alkyl ester having an alkyl group having 2 to 8 carbon atoms is preferably used as the (meth)acrylic acid alkyl ester in combination with the methyl (meth)acrylate because excellent printing properties etc. can be provided in both the case where a water-based ink is used and the case where a solvent-based ink is used.

Examples of the (meth)acrylic acid alkyl ester having an alkyl group having 2 to 12 carbon atoms include ethyl (meth)acrylate, n-butyl (meth)acrylate, i-butyl (meth)acrylate, t-butyl (meth)acrylate, and 2-ethylhexyl (meth)acrylate. Ethyl (meth)acrylate and n-butyl (meth)acrylate are more preferably used from the standpoints that bleeding of a printed image does not easily occur in both the case where a water-based ink is used and the case where a solvent-based ink is used and that, for example, a conductive pattern having an excellent fine-line-forming property is formed.

In particular, when excellent printing properties are desired in the formation of a printed image using a water-based pigment ink, among the (meth)acrylic acid alkyl esters having an alkyl group having 2 to 12 carbon atoms, ethyl (meth)acrylate is more preferably used.

Besides the above particular (meth)acrylic acid alkyl esters, for example, hydroxyalkyl (meth)acrylates such as 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, (4-hydroxymethylcyclohexyl)methyl (meth)acrylate, cyclohexyl methacrylate, isobornyl methacrylate, glycidyl methacrylate, benzyl methacrylate, tetrahydrofurfuryl methacrylate, allyl methacrylate, 2-methoxyethyl methacrylate, and 2-ethoxyethyl methacrylate; and alkoxyalkyl (meth)acrylates, 2-methoxyethyl (meth)acrylate, 2-ethoxyethyl (meth)acrylate, methoxytriethylene glycol (meth)acrylate, tetrahydrofurfuryl (meth)acrylate, ethylcarbitol (meth)acrylate, and the like whose hydroxyl groups are blocked are preferably used because bleeding of a printed image does not easily occur even in the case where a water-based ink, in particular, a water-based pigment ink is used and a conductive pattern having an excellent fine-line-forming property etc. can be formed. At least one selected from the group consisting of 2-hydroxyethyl (meth)acrylate, 2-hydroxypropyl (meth)acrylate, 2-hydroxybutyl (meth)acrylate, and 4-hydroxybutyl (meth)acrylate is more preferably used.

As described above, in order to improve printing properties in the case where a water-based ink, in particular, a water-based pigment ink is used, it is preferable to use at least one selected from the group consisting of hydroxyalkyl (meth)acrylates and (meth)acrylic acid alkyl esters having an alkyl group having 2 to 12 carbon atoms. These compounds are preferably used in a total amount in the range of 5% to 60% by mass and more preferably 35% to 60% by mass relative to the total amount of the vinyl monomer mixture.

Examples of the other vinyl monomers that can be used in the production of the vinyl resin (A1) include vinyl acetate, vinyl propionate, vinyl butyrate, vinyl versatate, methyl vinyl ether, ethyl vinyl ether, propyl vinyl ether, butyl vinyl ether, amyl vinyl ether, hexyl vinyl ether, (meth)acrylonitrile, styrene, α-methylstyrene, vinyl toluene, vinylanisole, α-halostyrene, vinyl naphthalene, divinylstyrene, isoprene, chloroprene, butadiene, ethylene, tetrafluoroethylene, vinylidene fluoride, N-vinylpyrrolidone, polyethylene glycol mono(meth)acrylate, glycerol mono(meth)acrylate, and salts thereof.

Vinyl monomers having a cross-linkable functional group can be used as the other vinyl monomers from the standpoint of introducing, into the vinyl resin (A1), the cross-linkable functional group such as at least one amide group selected from the group consisting of a methylolamide group and alkoxymethylamide groups, an amide group other than the above amide groups, a hydroxyl group, a glycidyl group, an amino group, a silyl group, an aziridinyl group, an isocyanate group, an oxazoline group, a cyclopentenyl group, an allyl group, a carbonyl group, or an acetoacetyl group.

Examples of the vinyl monomer having at least one amide group selected from the group consisting of a methylolamide group and alkoxymethylamide groups, the vinyl monomer being capable of being used as the vinyl monomer having a cross-linkable functional group, include N-methylol(meth)acrylamide, N-methoxymethyl(meth)acrylamide, N-methoxyethoxymethyl(meth)acrylamide, N-ethoxymethyl(meth)acrylamide, N-propoxymethyl(meth)acrylamide, N-isopropoxymethyl(meth)acrylamide, N-n-butoxymethyl(meth)acrylamide, N-isobutoxymethyl(meth)acrylamide, N-pentoxymethyl(meth)acrylamide, N-ethoxymethyl-N-methoxymethyl(meth)acrylamide, N,N′-dimethylol(meth)acrylamide, N-ethoxymethyl-N-propoxymethyl(meth)acrylamide, N,N′-dipropoxymethyl(meth)acrylamide, N-butoxymethyl-N-propoxymethyl(meth)acrylamide, N,N-dibutoxymethyl(meth)acrylamide, N-butoxymethyl-N-methoxymethyl(meth)acrylamide, N,N′-dipentoxymethyl(meth)acrylamide, and N-methoxymethyl-N-pentoxymethyl(meth)acrylamide.

Among these, N-n-butoxymethyl(meth)acrylamide and N-isobutoxymethyl(meth)acrylamide are preferably used from the standpoint of obtaining printed matter having excellent printing properties and high durability, a conductive pattern having an excellent fine-line-forming property and high durability, etc.

Examples of the vinyl monomers having a cross-linkable functional group include, in addition to the above-described vinyl monomers, vinyl monomers having an amide group, such as (meth)acrylamide; vinyl monomers having a hydroxyl group, such as (4-hydroxymethylcyclohexyl)methyl (meth)acrylate, glycerol (meth)acrylate, polyethylene glycol (meth)acrylate, N-hydroxyethyl(meth)acrylamide, N-hydroxypropyl(meth)acrylamide, and N-hydroxybutylacrylamide; polymerizable monomers having a glycidyl group, such as glycidyl (meth)acrylate and allyl glycidyl ether (meth)acrylate; polymerizable monomers having an amino group, such as aminoethyl (meth)acrylate, N-monoalkylaminoalkyl (meth)acrylate, and N,N-dialkylaminoalkyl (meth)acrylate; polymerizable monomers having a silyl group, such as vinyltrichlorosilane, vinyltrimethoxysilane, vinyltriethoxysilane, vinyltris(β-methoxyethoxy)silane, γ-(meth)acryloxypropyltrimethoxysilane, γ-(meth)acryloxypropyltriethoxysilane, γ-(meth)acryloxypropylmethyldimethoxysilane, γ-(meth)acryloxypropylmethyldiethoxysilane, γ-(meth)acryloxypropyltriisopropoxysilane, N-β-(N-vinylbenzylaminoethyl)-γ-aminopropyltrimethoxysilane, and hydrochlorides thereof; polymerizable monomers having an aziridinyl group, such as 2-aziridinylethyl (meth)acrylate; polymerizable monomers having an isocyanate group and/or a blocked isocyanate group, such as (meth)acryloyl isocyanate and a phenol or methyl ethyl ketoxime adduct of ethyl (meth)acryloyl isocyanate; polymerizable monomers having an oxazoline group, such as 2-isopropenyl-2-oxazoline and 2-vinyl-2-oxazoline; polymerizable monomers having a cyclopentenyl group, such as dicyclopentenyl (meth)acrylate; polymerizable monomers having an allyl group, such as allyl (meth)acrylate; and polymerizable monomers having a carbonyl group, such as acrolein and diacetone (meth)acrylamide.

Vinyl monomers having a hydroxyl group, such as hydroxyalkyl (meth)acrylates, which are exemplified as vinyl monomers capable of being used for further improving printing properties for a water-based pigment ink, can also be used as the vinyl monomers having a cross-linkable functional group.

As described above, N-butoxymethyl(meth)acrylamide and N-isobutoxymethyl(meth)acrylamide, which can undergo a self-cross-linking reaction by, for example, heating, are preferably used as the vinyl monomers having a cross-linkable functional group. Any of these compounds is preferably used alone or in combination with (meth)acrylamide or a vinyl monomer having a hydroxyl group, such as 2-hydroxybutyl (meth)acrylate.

In the case where a cross-linking agent (D) described below is used, 2-hydroxyethyl (meth)acrylate, 2-hydroxypropyl (meth)acrylate, and 4-hydroxybutyl (meth)acrylate are more preferably used in order to introduce a functional group such as a hydroxyl group or a carboxyl group, which can function as a cross-linking point with the cross-linking agent (D). The use of the vinyl monomers having a hydroxyl group is preferable when an isocyanate cross-linking agent is used as a cross-linking agent described below.

The vinyl monomer having a cross-linkable functional group can be used in the range of 0% to 50% by mass relative to the total amount of the vinyl monomer mixture. In the case where the cross-linking agent (D) undergoes a self-cross-linking reaction, the vinyl monomer having a cross-linkable functional group is not necessarily used.

Among the vinyl monomers having a cross-linkable functional group, the vinyl monomer having an amide group is preferably used in the range of 0.1% to 50% by mass, and more preferably in the range of 1% to 30% by mass relative to the total amount of the vinyl monomer mixture from the standpoint of introducing a self-cross-linking reactive methylolamide group or the like. Another vinyl monomer having an amide group other than the above amide group or another vinyl monomer having a hydroxyl group, the vinyl monomer being used in combination with the self-cross-linking reactive methylolamide group, is preferably used in the range of 0.1% to 30% by mass, and more preferably in the range of 1% to 20% by mass relative to the total amount of the vinyl monomers used in the production of the vinyl resin (A).

Among the vinyl monomers having a cross-linkable functional group, the vinyl monomer having a hydroxyl group or the vinyl monomer having an acid group is preferably used in the range of about 0.05% to 50% by mass, more preferably in the range of about 0.05% to 30% by mass, and still more preferably in the range of about 0.1% to 10% by mass relative to the total amount of the vinyl monomer mixture, though the amount depends on, for example, the type of cross-linking agent (D) that is used in combination.

Next, a method for producing the vinyl resin (A1) will be described.

The vinyl monomer (A1) can be produced by polymerizing the vinyl monomer mixture described above by a known method, and is preferably produced by an emulsion polymerization method.

Examples of the emulsion polymerization method that can be used include a method in which water, a vinyl monomer mixture, a polymerization initiator, and as required, a chain transfer agent, an emulsifier, a dispersion stabilizer, etc. are supplied in a reaction vessel at one time, mixed, and polymerized; a monomer-dropping method in which a vinyl monomer mixture is added dropwise to a reaction vessel and polymerized; and a pre-emulsion method in which a mixture prepared by mixing a vinyl monomer mixture, an emulsifier or the like, and water in advance is added dropwise to a reaction vessel and polymerized.

The reaction temperature of the emulsion polymerization method is preferably, for example, about 30° C. to 90° C., though the reaction temperature varies depending on the types of vinyl monomers and polymerization initiator used. The reaction time of the emulsion polymerization method is preferably, for example, about 1 to 10 hours.

Examples of the polymerization initiator include persulfates such as potassium persulfate, sodium persulfate, and ammonium persulfate; organic peroxides such as benzoyl peroxide, cumene hydroperoxide, and t-butyl hydroperoxide; and hydrogen peroxide. The polymerization can be conducted by radical polymerization using any of these peroxides alone. Alternatively, the polymerization can be conducted by using a redox polymerization initiator in which the above peroxide is used in combination with a reducing agent such as ascorbic acid, a metal salt of formaldehyde sulfoxylate, sodium thiosulfate, sodium bisulfite, or ferric chloride; or by using an azo initiator such as 4,4′-azobis(4-cyanovaleric acid) or 2,2′-azobis(2-amidinopropane) dihydrochloride. These polymerization initiators may be used alone or in combination as a mixture of two or more compounds.

Examples of the emulsifier that can be used in the production of the vinyl resin (A1) include anionic surfactants, nonionic surfactants, cationic surfactants, and amphoteric surfactants. Among these, anionic surfactants are preferably used.

Examples of the anionic surfactant include sulfuric acid esters of higher alcohols and salts thereof, alkylbenzenesulfonic acid salts, polyoxyethylene alkylphenyl sulfonic acid salts, polyoxyethylene alkyl diphenyl ether sulfonic acid salts, sulfuric acid half-ester salts of polyoxyethylene alkyl ethers, alkyl diphenyl ether disulfonic acid salts, and succinic acid dialkyl ester sulfonic acid salts. Examples of the nonionic surfactant that can be used include polyoxyethylene alkyl ethers, polyoxyethylene alkyl phenyl ethers, polyoxyethylene diphenyl ether, polyoxyethylene-polyoxypropylene block copolymers, and acetylenediol-based surfactants.

Examples of the cationic surfactant that can be used includes alkyl ammonium salts.

Examples of the amphoteric surfactant that can be used include alkyl (amide) betaines and alkyl dimethyl amine oxides.

Examples of the emulsifier that can be used include, in addition to the above surfactants, fluorine-based surfactants, silicone-based surfactants, and emulsifiers each having a polymerizable unsaturated group in its molecule, which are generally referred to as “reactive emulsifiers”.

Examples of the reactive emulsifier that can be used include “LATEMUL S-180” (manufactured by Kao Corporation), “ELEMINOL JS-2 and RS-30” (manufactured by Sanyo Chemical Industries, Ltd.), all of which have a sulfonic acid group and a salt thereof; “Aquaron HS-10, HS-20, and KH-1025” (manufactured by Dai-ichi Kogyo Seiyaku Co., Ltd.), “ADEKA REASOAP SE-10 and SE-20” (manufactured by ADEKA Corporation), all of which have a sulfonic acid group and a salt thereof; “New Frontier A-229E” (manufactured by Dai-ichi Kogyo Seiyaku Co., Ltd.), which has a phosphate group; and “Aquaron RN-10, RN-20, RN-30, and RN-50” (manufactured by Dai-ichi Kogyo Seiyaku Co., Ltd.), all of which have a nonionic hydrophilic group.

The same as those exemplified as an aqueous medium (B) can be used as an aqueous medium used in the production of the vinyl resin (A1).

An example of the chain transfer agent that can be used in the production of the binder resin (A) such as the vinyl resin (A1) is lauryl mercaptan. The chain transfer agent is preferably used in the range of 0% to 0.15% by mass and more preferably in the range of 0% to 0.08% by mass relative to the total amount of the vinyl monomer mixture from the standpoint of forming an ink-receiving layer capable of forming a printed image having better printing properties in both the case where a water-based ink is used and the case where a solvent-based ink is used.

The content of the binder resin (A) such as the vinyl resin (A1) obtained by the method described above is preferably in the range of 5% to 60% by mass, and more preferably in the range of 10% to 50% by mass relative to the total amount of the resin composition for forming an ink-receiving layer according to the present invention.

Next, the aqueous medium (B) used in the production of the resin composition for forming an ink-receiving layer will be described.

The aqueous medium (B) is used to disperse the vinyl resin (A1). Water may be used alone, or a mixed solution of water and a water-soluble solvent may be used. Examples of the water-soluble solvent that can be used include polar solvents such as alcohols, e.g., methyl alcohol, ethyl alcohol, isopropyl alcohol, ethyl carbitol, ethyl cellosolve, and butyl cellosolve; and N-methylpyrrolidone.

The content of the aqueous medium (B) is preferably in the range of 35% to 95% by mass and more preferably in the range of 40% to 90% by mass relative to the total amount of the resin composition for forming an ink-receiving layer according to the present invention.

The resin composition for forming an ink-receiving layer according to the present invention may optionally contain various additives as long as the advantages of the present invention are not impaired. For example, additives that have been used in existing resin compositions for forming ink-receiving layers, such as a water-soluble resin (c1) and a filler (c2), can be suitably used. It is essential that the content of at least one component (C) selected from the group consisting of the water-soluble resin (c1) and the filler (c2) be in the range of 0% to 15% by mass relative to the total amount of the binder resin (A) such as the vinyl resin (A1) from the standpoint of forming an ink-receiving layer capable of forming a printed image having both high water resistance and excellent printing properties at such a level that bleeding or the like does not occur in both the case where a water-based ink is used and the case where a solvent-based ink is used.

Polyvinyl alcohol, polyvinylpyrrolidone, and the like, which are typical examples of the water-soluble resin (c1), are particularly used for the purpose of providing printing properties, a fine-line-forming property, and the like for water-based inks. However, the receiving layer for water-based inks cannot sufficiently receive solvent-based inks and generally causes bleeding of printed images, for example.

The resin composition for forming an ink-receiving layer according to the present invention can surprisingly receive a water-based ink and a solvent-based ink even when the water-soluble resin (c1) such as polyvinyl alcohol is not used or only a minimum amount of water-soluble resin (c1) is used. Thus, a receiving layer having excellent printing properties and an excellent fine-line-forming property can be formed even when either of the inks is used.

The content of the water-soluble resin (c1) is preferably in the range of 0% to 10% by mass, and more preferably 0% to 0.5% by mass from the standpoint of forming a receiving layer having excellent printing properties, an excellent fine-line-forming property, and high water resistance in both the case where a water-based ink is used and the case where a solvent-based ink is used.

Silica, alumina, starch, etc., which are typical examples of the filler (c2), are generally used in a large amount when a microporous ink-receiving layer is formed. When a swelling-type ink-receiving layer is formed, these fillers may be used in a small amount in order to provide blocking resistance to the ink-receiving layer.

The microporous ink receiving layer is also usually designed for either a water-based ink or a solvent-based ink. Therefore, it is often difficult to form a printed image having excellent printing properties and an excellent fine-line-forming property in both the case where a water-based ink is used and the case where a solvent-based ink is used.

In addition, when the filler (c2) is present in the ink-receiving layer, the adhesiveness of the ink-receiving layer to a substrate decreases and the transparency and flexibility of the ink-receiving layer also tend to decrease. Therefore, the resin composition may not be applied to a flexible substrate such as a film used in new fields such as a printed electronics field.

The resin composition for forming an ink-receiving layer according to the present invention can surprisingly receive a water-based ink and a solvent-based ink even when the filler (c2) such as silica is not used or only a minimum amount of filler (c2) is used. Thus, a receiving layer having excellent printing properties, an excellent fine-line-forming property, and high water resistance can be formed even when either of the inks is used.

The content of the filler (c2) is preferably 0% to 10% by mass, and particularly preferably 0% to 0.5% by mass relative to the total amount of the binder resin (A) such as the vinyl resin (A1) from the standpoint of forming a receiving layer having excellent printing properties, an excellent fine-line-forming property, and high water resistance in both the case where a water-based ink is used and the case where a solvent-based ink is used. In particular, when the resin composition for forming an ink-receiving layer is used in the production of a conductive pattern, the amount of the filler or the like used is preferably within the above range from the standpoint of preventing a decrease in the adhesiveness of the conductive pattern to a flexible substrate such as a film used in new fields such as a printed electronics field.

The resin composition for forming an ink-receiving layer according to the present invention may optionally contain known additives such as the cross-linking agent (D), a pH adjusting agent, a coating film-forming auxiliary agent, a leveling agent, a thickener, a water-repellent agent, and an antifoaming agent as long as the advantages of the present invention are not impaired.

Examples of the cross-linking agent (D) that can be used include a thermal cross-linking agent (d1-1) that reacts at a relatively low temperature of about 25° C. or higher and lower than 100° C. and can form a cross-linked structure, such as a metal chelate compound, a polyamine compound, an aziridine compound, a metal salt compound, or an isocyanate compound; a thermal cross-linking agent (d1-2) that reacts at a relatively high temperature of about 100° C. or higher and can form a cross-linked structure, such as at least one selected from the group consisting of melamine compounds, epoxy compounds, oxazoline compounds, carbodiimide compounds, and blocked isocyanate compounds; and photo-cross-linking agents.

In the case where a resin composition for forming an ink-receiving layer contains the thermal cross-linking agent (d1-1), for example, the resin composition is applied onto a surface of a substrate and dried at a relatively low temperature, printing is then conducted using an ink, and the resulting substrate is then heated to a temperature of lower than 100° C. to form a cross-linked structure. Thus, it is possible to form an ink-receiving base having high durability that can prevent detachment of a conductive substance, a pigment, etc. regardless of the influence of heat or an external force for a long time.

In the case where a resin composition for forming an ink-receiving layer contains the thermal cross-linking agent (d1-2), for example, the resin composition is applied onto a surface of a substrate and dried at a low temperature in the range of room temperature (25° C.) to lower than about 100° C. to produce an ink-receiving base in which a cross-linked structure is not formed, printing is then conducted using an ink or the like, and the resulting ink-receiving base is then heated to a temperature of 100° C. or higher and preferably 120° C. or higher to form a cross-linked structure. Thus, it is possible to obtain printed matter and a conductive pattern that have high durability at such a level that, for example, detachment of an ink is not caused regardless of the influence of heat, an external force, or the like for a long time.

Examples of the metal chelate compound that can be used as the thermal cross-linking agent (d1-1) include acetylacetone coordination compounds and acetoacetic ester coordination compounds of a polyvalent metal such as aluminum, iron, copper, zinc, tin, titanium, nickel, antimony, magnesium, vanadium, chromium, or zirconium. Acetylacetone aluminum, which is an acetylacetone coordination compound of aluminum, is preferably used.

Examples of the polyamine compound that can be used as the thermal cross-linking agent (d1-1) include tertiary amines such as triethylamine, triethylenediamine, and dimethylethanolamine.

Examples of the aziridine compound that can be used as the thermal cross-linking agent (d1-1) include 2,2-bishydroxymethylbutanol-tris[3-(1-aziridinyl)propionate], 1,6-hexamethylenediethyleneurea, and diphenylmethane-bis-4,4′-N,N′-diethyleneurea.

Examples of the metal salt compound that can be used as the thermal cross-linking agent (d1-1) include water-soluble metal salts such as aluminum-containing compounds, e.g., aluminum sulfate, aluminum alum, aluminum sulfite, aluminum thiosulfate, polyaluminum chloride, aluminum nitrate nonahydrate, and aluminum chloride hexahydrate; titanium tetrachloride; tetraisopropyl titanate; titanium acetylacetonate; and titanium lactate.

Examples of the isocyanate compound that can be used as the thermal cross-linking agent (d1-1) include polyisocyanates such as tolylene diisocyanate, hydrogenated tolylene diisocyanate, triphenylmethane triisocyanate, methylenebis(4-phenylmethane) triisocyanate, isophorone diisocyanate, hexamethylene diisocyanate, and xylylene diisocyanate; isocyanurate-type polyisocyanate compounds obtained using any of these polyisocyanates; adducts of any of these polyisocyanates and trimethylolpropane or the like; and polyisocyanate group-containing urethanes obtained by reacting any of the polyisocyanate compounds with a polyol such as trimethylolpropane. Among these, an isocyanurate of hexamethylene diisocyanate, an adduct of hexamethylene diisocyanate and trimethylolpropane or the like, an adduct of tolylene diisocyanate and trimethylolpropane or the like, or an adduct of xylylene diisocyanate and trimethylolpropane or the like is preferably used.

Examples of the melamine compound that can be used as the thermal cross-linking agent (d1-2) include hexamethoxymethylmelamine, hexaethoxymethylmelamine, hexapropoxymethylmelamine, hexabutoxymethylmelamine, hexapentyloxymethylmelamine, hexahexyloxymethylmelamine, and mixed etherified melamines obtained by using two of these melamine compounds in combination. In particular, trimethoxymethylmelamine or hexamethoxymethylmelamine is preferably used. Examples of a commercially available product that can be used include Beckamine M-3, APM, and J-101 (manufactured by DIC Corporation).

In the case where the melamine compound is used, a catalyst such as an organic amine salt may be used in order to accelerate a self-cross-linking reaction of the melamine compound. Examples of a commercially available product that can be used include Catalyst ACX, 376, etc. The content of the catalyst is preferably in the range of about 0.01% to 10% by mass relative to the total amount of the melamine compound.

Examples of the epoxy compound that can be used as the thermal cross-linking agent (d1-2) include polyglycidyl ethers of aliphatic polyhydric alcohols such as ethylene glycol diglycidyl ether, propylene glycol diglycidyl ether, hexamethylene glycol diglycidyl ether, cyclohexanediol diglycidyl ether, glycerin diglycidyl ether, glycerin triglycidyl ether, trimethylolpropane triglycidyl ether, and pentaerythritol tetraglycidyl ether; polyglycidyl ethers of polyalkylene glycols such as polyethylene glycol diglycidyl ether, polypropylene glycol diglycidyl ether, and polytetramethylene glycol diglycidyl ether; polyglycidylamines such as 1,3-bis(N,N′-diglycidylaminoethyl)cyclohexane; polyglycidyl esters of polyvalent carboxylic acids [such as oxalic acid, adipic acid, butanetricarboxylic acid, maleic acid, phthalic acid, terephthalic acid, isophthalic acid, or benzene tricarboxylic acid]; bisphenol A epoxy resins such as a condensate of bisphenol A and epichlorohydrin and an ethylene oxide adduct of a condensate of bisphenol A and epichlorohydrin; phenol novolac resins; and vinyl (co)polymers having an epoxy group in a side chain thereof. Among these, polyglycidylamines such as 1,3-bis(N,N′-diglycidylaminoethyl)cyclohexane and polyglycidyl ethers of aliphatic polyhydric alcohols, such as glycerin diglycidyl ether, are preferably used.

Examples of the epoxy compound that can be used include, in addition to the compounds described above, glycidyl group-containing silane compounds such as γ-glycidoxypropyltrimethoxysilane, γ-glycidoxypropyltriethoxysilane, γ-glycidoxypropylmethyldimethoxysilane, γ-glycidoxypropylmethyldiethoxysilane, β-(3,4-epoxycyclohexyl)ethyltrimethoxysilane, β-(3,4-epoxycyclohexypethyltriethoxysilane, β-(3,4-epoxycyclohexyl)ethylmethyldiethoxysilane, and γ-glycidoxypropyltriisopropenyloxysilane.

Examples of the oxazoline compound that can be used as the thermal cross-linking agent (d1-2) include 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane)sulfide, and bis-(2-oxazolinylnorbornane)sulfide.

Examples of the oxazoline compound that can be used further include oxazoline group-containing polymers obtained by polymerizing an addition-polymerizable oxazoline described below and, as required, another monomer in combination.

Examples of the addition-polymerizable oxazoline include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-methyl-2-oxazoline, and 2-isopropenyl-5-ethyl-2-oxazoline. These may be used alone or in combination of two or more compounds. Among these, 2-isopropenyl-2-oxazoline is preferably used because it is industrially easily available.

Examples of the carbodiimide compound that can be used as the thermal cross-linking agent (d1-2) include poly[phenylenebis(dimethylmethylene)carbodiimide] and poly(methyl-1,3-phenylenecarbodiimide). Examples of commercially available products that can be used include Carbodilite V-01, V-02, V-03, V-04, V-05, and V-06 (manufactured by Nisshinbo Chemical Inc.) and UCARLINK XL-29SE and XL-29MP (manufactured by Union Carbide Corporation).

Examples of the blocked isocyanate compound that can be used as the thermal cross-linking agent (d1-2) include compounds in which some or all of isocyanate groups in the isocyanate compounds exemplified as the thermal cross-linking agent (d1-1) are blocked by a blocking agent.

Examples of the blocking agent that can be used include phenol, cresol, 2-hydroxypyridine, butyl cellosolve, propylene glycol monomethyl ether, benzyl alcohol, methanol, ethanol, n-butanol, isobutanol, dimethyl malonate, diethyl malonate, methyl acetoacetate, ethyl acetoacetate, acetylacetone, butyl mercaptan, dodecyl mercaptan, acetanilide, acetic acid amide, ε-caprolactam, δ-valerolactam, γ-butyrolactam, succinimide, maleimide, imidazole, 2-methylimidazole, urea, thiourea, ethylene urea, formamide oxime, acetaldoxime, acetone oxime, methyl ethyl ketoxime, methyl isobutyl ketoxime, cyclohexanone oxime, diphenylaniline, aniline, carbazole, ethyleneimine, and polyethylene imine.

An example of the blocked isocyanate compound that can be used is Elastron BN-69 (manufactured by Dai-ichi Kogyo Seiyaku Co., Ltd.), which is a water-dispersion type commercially available product.

In the case where the cross-linking agent (D) is used, a vinyl resin having a group that can react with the cross-linkable functional group in the cross-linking agent (D) is preferably used as the vinyl resin (A1). Specifically, the (blocked) isocyanate compounds, the melamine compounds, the oxazoline compounds, and the carbodiimide compounds are used as the cross-linking agent (d), and a vinyl resin having a hydroxyl group or a carboxyl group is preferably used as the vinyl resin (A).

In general, the content of the cross-linking agent (D) is preferably in the range of 0.01% to 60% by mass and more preferably in the range of 0.1% to 50% by mass relative to the amount of the vinyl resin (A) from the standpoint of obtaining printed matter having excellent printing properties and high durability, a conductive pattern having an excellent fine-line-forming property and high durability, etc., though the content of the cross-linking agent (D) varies depending on, for example, the type of cross-linking agent (D).

In particular, the content of the melamine compound serving as the cross-linking agent (D) is preferably in the range of 0.1% to 30% by mass, more preferably in the range of 0.1% to 10% by mass, and still more preferably in the range of 0.5% to 5% by mass relative to the amount of the vinyl resin (A) because the melamine compound undergoes a self-condensation reaction.

The cross-linking agent (D) is preferably added in advance to the resin composition for forming an ink-receiving layer according to the present invention before the resin composition is applied onto or impregnated into a surface of a substrate.

The resin composition for forming an ink-receiving layer according to the present invention may contain, in addition to the additives described above, solvent-soluble or solvent-dispersible thermosetting resins such as a phenolic resin, a urea resin, a melamine resin, a polyester resin, a polyamide resin, and a urethane resin.

An ink-receiving layer that can be formed by using the resin composition for forming an ink-receiving layer is a swelling-type ink-receiving layer in which the binder resin (A) such as the vinyl resin (A1) is appropriately dissolved by a solvent contained in an ink and absorbs the solvent, and thus a pigment and a conductive substance such as a metal that are contained in the ink can be fixed to a surface of the ink-receiving layer with a high accuracy. Therefore, printed matter such as a bleeding-free conductive pattern can be obtained. Furthermore, the resin composition for forming an ink-receiving layer according to the present invention can form a transparent ink-receiving layer compared with a known porous ink-receiving layer.

Next, an ink-receiving base according to the present invention will now be described.

The receiving base according to the present invention includes an ink-receiving layer formed on part or the entirety of a surface of a substrate and on either one surface or both surfaces of the substrate by using the resin composition for forming an ink-receiving layer. The ink-receiving layer may be stacked on the substrate. Alternatively, part of the ink-receiving layer may be impregnated into the substrate.

The ink-receiving base according to the present invention can be produced by applying the ink-receiving base onto either one surface or both surfaces of a substrate or by impregnating the receiving base into a substrate when the substrate is a fibrous base or the like, and then volatilizing the aqueous medium (B) contained in the resin composition for forming an ink-receiving layer.

Examples of the substrate that can be used include not only wood-free paper and coated paper but also substrates composed of a polyimide resin, a polyamide-imide resin, a polyamide resin, polyethylene terephthalate, polyethylene naphthalate, polycarbonate, acrylonitrile-butadiene-styrene (ABS), an acrylic resin such as polymethyl (meth)acrylate, polyvinylidene fluoride, polyvinyl chloride, polyvinylidene chloride, polyvinyl alcohol, polyethylene, polypropylene, polyurethane, cellulose nanofibers, silicon, a ceramic, or glass; porous substrates composed of any of these materials; and substrates composed of a metal such as copper or a steel sheet.

Examples of the substrate that can be used further include bases composed of synthetic fibers such as polyester fibers, polyamide fibers, or aramid fibers; and bases composed of natural fibers such as cotton or hemp. These fibers may be processed in advance.

Publicly known methods can be employed as a method for applying the resin composition for forming an ink-receiving layer onto the substrate or impregnating the substrate with the resin composition. Examples of the method include a gravure method, a coating method, a screen method, a roller method, a rotary method, and a spray method.

A method for volatilizing the aqueous medium (B) contained in the ink-receiving layer after the resin composition for forming an ink-receiving layer according to the present invention is applied onto or impregnated into a substrate is not particularly limited, but, for example, a drying method using a dryer is commonly used. The drying temperature may be set to a temperature in a range in which the aqueous medium (B) can be volatilized and the substrate is not adversely affected.

A method for removing a solvent that may be contained in the resin composition for forming an ink-receiving layer according to the present invention after the resin composition is applied onto or impregnated into part or the entirety of a surface of a substrate is not particularly limited, but, for example, a drying method using a dryer is commonly used. The drying temperature may be set to a temperature in a range in which the solvent can be volatilized and the substrate is not adversely affected. Specifically, in the case where the thermal cross-linking agent (d1-1) is used, drying is preferably performed at a temperature of about 25° C. or higher and lower than 100° C. In the case where the thermal cross-linking agent (d1-2) is used, drying is preferably performed at a temperature of about 100° C. or higher, more preferably at a temperature in the range of about 120° C. to 300° C. In the case where the thermal cross-linking agent (d1-2) is used, printing is performed with an ink or the like, and a cross-linked structure is then formed, drying is preferably performed at a relatively low temperature of about room temperature (25° C.) to 100° C. so that a cross-linked structure is not formed before the printing.

The amount of the resin composition for forming an ink-receiving layer, the resin composition adhering to the substrate, is preferably in the range of 10 to 60 g/m² with respect to the area of the substrate from the standpoint of maintaining a very high level of color-developing property and maintaining a good production efficiency, and particularly preferably in the range of 20 to 40 g/m² considering the absorbency of an ink and the production cost.

By increasing the amount of the resin composition for forming an ink-receiving layer, the resin composition adhering to the substrate, the color-developing property of the resulting printed matter can be further improved. However, an increase in the amount of the resin composition adhering to the substrate tends to make the texture of the resulting printed matter somewhat hard. Accordingly, it is preferable to appropriately adjust the amount of the resin composition in accordance with, for example, the use of the printed matter.

Printing can be performed on the ink-receiving base according to the present invention obtained by the above method using either of a water-based ink and a solvent-based ink. Even in the case where either of the inks is used, a printed image having excellent printing properties and excellent water resistance can be formed without causing bleeding or cracks.

A printed image having good printing properties and good water resistance can be formed on the ink-receiving base according to the present invention without causing bleeding or cracks, and thus the ink-receiving base according to the present invention can be used in, for example, indoor and outdoor advertisements such as a signboard, advertisement on vehicles, and a banner.

The water-based ink that can be used in the printing is an ink containing a solvent composed of an aqueous medium and a pigment etc. that are dissolved or dispersed in the solvent. As for the aqueous medium that can be used as the solvent of the water-based ink, water may be used alone or a mixed solution of water and a water-soluble solvent may be used. Examples of the water-soluble solvent that can be used include polar solvents such as alcohols, e.g., methyl alcohol, ethyl alcohol, isopropyl alcohol, ethyl carbitol, ethyl cellosolve, and butyl cellosolve; and N-methylpyrrolidone.

Examples of the pigment that can be dispersed or dissolved in the aqueous medium include organic pigments such as quinacridone-based pigments, anthraquinone-based pigments, perylene-based pigments, perinone-based pigments, diketopyrrolopyrrole-based pigments, isoindolinone-based pigments, condensed azo-based pigments, benzimidazolone-based pigments, monoazo-based pigments, insoluble azo-based pigments, naphthol-based pigments, flavanthrone-based pigments, anthrapyrimidine-based pigments, quinophthalone-based pigments, pyranthrone-based pigments, pyrazolone-based pigments, thioindigo-based pigments, anthanthrone-based pigments, dioxazine-based pigments, phthalocyanine-based pigments, and indanthrone-based pigments; metal complexes such as nickel dioxin yellow and copper azomethine yellow; metal oxides such as titanium oxide, iron oxide, and zinc oxide; metal salts such as barium sulfate and calcium carbonate; inorganic pigments such as carbon black and mica; fine powders of a metal such as aluminum; and fine powders of mica. The pigment is preferably used in the range of 0.5% to 15% by mass, and more preferably 1% to 10% by mass relative to the total amount of water-based ink.

The solvent-based ink that can be used is an ink containing a solvent composed of an organic solvent and a pigment etc. that are dissolved or dispersed in the solvent.

Alcohols, ethers, esters, ketones, etc. which have a boiling point of 100° C. to 250° C. are preferably used, and those having a boiling point of 120° C. to 220° C. are more preferably used as the organic solvent from the standpoint of, for example, preventing the drying and clogging of an ink jet head.

Examples of the alcohols that can be used include ethylene glycol, triethylene glycol, tetraethylene glycol, propylene glycol, and dipropylene glycol.

Examples of the ethers that can be used include ethylene glycol mono(methyl, ethyl, butyl, phenyl, benzyl, and ethylhexyl) ethers, ethylene glycol di(methyl, ethyl, and butyl) ethers, diethylene glycol mono(methyl, ethyl, and butyl) ethers, diethylene glycol di(methyl, ethyl, butyl) ethers, tetraethylene glycol mono(methyl, ethyl, and butyl) ethers, tetraethylene glycol di(methyl, ethyl, and butyl) ethers, propylene glycol mono(methyl, ethyl, and butyl) ethers, dipropylene glycol mono(methyl and ethyl) ethers, and tripropylene glycol monomethyl ether.

Examples of the esters include ethylene glycol mono(methyl, ethyl, and butyl) ether acetates, ethylene glycol di(methyl, ethyl, and butyl) ether acetates, diethylene glycol mono(methyl, ethyl, and butyl) ether acetates, diethylene glycol di(methyl, ethyl, and butyl) ether acetates, propylene glycol mono(methyl, ethyl, and butyl) ether acetates, dipropylene glycol mono(methyl and ethyl) ether acetates, tripropylene glycol monomethyl ether acetate, 2-(methoxy, ethoxy, and butoxy)ethyl acetates, 2-ethylhexyl acetate, dimethyl phthalate, diethyl phthalate, and butyl lactate. An example of the ketones is cyclohexanone.

Among these organic solvents, diethylene glycol diethyl ether, tetraethylene glycol monobutyl ether, tetraethylene glycol dimethyl ether, ethylene glycol monobutyl ether acetate, and propylene glycol monomethyl ether acetate are preferably used.

The same as those exemplified as the pigments that can be used in the water-based ink can be used as the pigment used in the solvent-based ink.

Various printing methods can be employed as a method for performing printing on the ink-receiving base according to the present invention with the ink. An ink-jet printing method is preferably employed.

The ink-receiving base according to the present invention has excellent printing properties also for an ink containing a conductive substance. For example, a fine line having a width of about 0.01 to 200 μm and preferably about 0.01 to 150 μm, which is required for forming a conductive pattern of an electronic circuit or the like, can be printed without causing bleeding (fine-line-forming property). Accordingly, the ink-receiving base according to the present invention can also be suitably used in, for example, the printed electronics field, such as the formation of an electronic circuit using a silver ink or the like, the formation of layers and peripheral wiring that are included in an organic solar cell, an electronic book terminal, an organic EL device, an organic transistor, a flexible printed circuit board, RFID, etc., and the formation of wiring of an electromagnetic wave shield of a plasma display.

A conductive-ink-receiving base that can be used for forming the conductive pattern includes a substrate and a conductive-ink-receiving layer disposed on part or the entirety of a surface of a substrate, the conductive-ink-receiving layer being formed by using the resin composition for forming an ink-receiving layer, as in the ink-receiving base described above. The conductive-ink-receiving layer may be stacked on the substrate. Alternatively, part of the conductive-ink-receiving layer may be impregnated into the substrate. The conductive-ink-receiving layer may be provided on either one surface or both surfaces of the substrate, and may be applied onto part or the entirety of the one or two surfaces.

The conductive-ink-receiving base according to the present invention can be produced by applying a resin composition for forming a conductive-ink-receiving layer onto part or the entirety of one surface or both surfaces of a substrate or by impregnating the resin composition into part of or the entirety of one or two surfaces of a substrate, and then removing the aqueous medium (B) contained in the resin composition for forming a conductive-ink-receiving layer.

Examples of the substrate suitable for stacking the conductive-ink-receiving layer thereon include substrates composed of a polyimide resin, a polyamide-imide resin, a polyamide resin, polyethylene terephthalate, polyethylene naphthalate, polycarbonate, acrylonitrile-butadiene-styrene (ABS), an acrylic resin such as polymethyl (meth)acrylate, polyvinylidene fluoride, polyvinyl chloride, polyvinylidene chloride, polyvinyl alcohol, polycarbonate, polyethylene, polypropylene, polyurethane, cellulose nanofibers, silicon, a ceramic, or glass; porous substrates composed of any of these materials; and substrates composed of a metal such as copper or a steel sheet.

Among these, substrates composed of a polyimide resin, polyethylene terephthalate, polyethylene naphthalate, glass, cellulose nanofibers, or the like, all of which are often used as a substrate on which a conductive pattern of a circuit board or the like is formed, are preferably used as the substrate.

Among the above substrates, bases composed of a polyimide resin, polyethylene terephthalate, polyethylene naphthalate, polycarbonate, acrylonitrile-butadiene-styrene (ABS), an acrylic resin, glass, or the like generally have low adhesiveness, and thus a resin or the like often does not easily adhere to the substrate.

In the case where the substrate is used in, for example, an application that requires flexibility, a substrate that is relatively flexible and that can be bent, for example, is preferably used from the standpoint of providing flexibility to a conductive pattern and obtaining a final product that can be bent. Specifically, for example, a uniaxially stretched film-like or sheet-like substrate is preferably used.

Examples of the film-like or sheet-like substrate include a polyethylene terephthalate film, a polyimide film, and a polyethylene naphthalate film.

Publicly known methods can be employed as a method for applying the resin composition for forming an ink-receiving layer onto part or the entirety of a surface of the substrate or impregnating part or the entirety of a surface of the substrate with the resin composition. Examples of the method include a gravure method, a coating method, a screen method, a roller method, a rotary method, a spray method, and an ink-jet method.

A method for removing the aqueous medium (B) that may be contained in the resin composition for forming an ink-receiving layer according to the present invention after the resin composition is applied onto or impregnated into part or the entirety of a surface of a substrate is not particularly limited, but a drying method using a dryer is commonly used. The drying temperature may be set to a temperature in a range in which the solvent can be volatilized and the substrate is not adversely affected.

The amount of the resin composition for forming an ink-receiving layer, the resin composition adhering to a surface of the substrate, is preferably in the range of 0.1 to 50 g/m² in terms of resin solid content with respect to the area of the substrate considering the amount of solvent contained in a conductive ink, the thickness of a conductive pattern, and the like. The amount of the resin composition adhering to a surface of the substrate is particularly preferably in the range of 0.5 to 40 g/m² considering the absorbency of a conductive ink and the production cost.

By increasing the amount of the resin composition for forming an ink-receiving layer, the resin composition adhering to a surface of the substrate, the fine-line-forming property of the conductive-ink-receiving base can be further improved. However, an increase in the amount of the resin composition adhering to the substrate tends to make the texture of the resulting conductive-ink-receiving base somewhat hard. Accordingly, for example, in the case where good flexibility is required, e.g., in the case of an organic EL device that can be bent, the amount of the resin composition is preferably in the range of about 0.5 to 30 g/m² so that the film thickness of the resin composition becomes relatively small. Alternatively, the resin composition may be used in an embodiment in which the amount of the resin composition is in the range of about 10 to 100 g/m² so that the film thickness of the resin composition becomes relatively large depending on, for example, the use of the conductive-ink-receiving base.

The conductive-ink-receiving base according to the present invention produced by the method described above can be particularly suitably used for forming a conductive pattern or the like in the printed electronics field described above. More specifically, the conductive-ink-receiving base can be suitably used as a substrate for forming a circuit, the substrate being used in an electronic circuit, an integrated circuit, or the like.

Printing can be performed on the conductive-ink-receiving base or the substrate for forming a circuit by using a conductive ink. Specifically, printing is performed on a conductive-ink-receiving layer of the conductive-ink-receiving base with a conductive ink, and a baking step is then performed. Thus, for example, a conductive pattern including a conductive substance which is a metal such as silver, the conductive substance being contained in the conductive ink, can be formed on the conductive-ink-receiving base.

For example, an ink that contains a conductive substance, a solvent, and as required, additives such as a dispersing agent can be used as the conductive ink.

Examples of the conductive substance that can be used include transition metals and compounds thereof. Among these, ionic transition metals are preferably used. For example, transition metals such as copper, silver, gold, nickel, palladium, platinum, and cobalt are preferably used, and silver, gold, copper, etc. are more preferably used because a conductive pattern that has a low electrical resistance and that is highly resistant to corrosion can be formed.

Particulate conductive substances having an average particle size of about 1 to 50 nm are preferably used as the conductive substance. Herein, the term “average particle size” refers to a center particle size (D50) and a value measured with a laser diffraction/scattering particle size distribution analyzer.

The conductive substance such as a metal is preferably contained in the range of 10% to 60% by mass relative to the total amount of the conductive ink.

Various types of organic solvents and aqueous media such as water can be used as the solvent in the conductive ink.

In the present invention, solvent-based conductive inks that mainly contain an organic solvent as the solvent of the conductive ink, water-based conductive inks that mainly contain water as the solvent, and conductive inks that contain both an organic solvent and water can be appropriately selected and used.

Among these, from the standpoint of improving the fine-line-forming property, adhesiveness, etc. of, for example, a conductive pattern to be formed, conductive inks that contain both an organic solvent and water as the solvent of the conductive ink and solvent-based conductive inks that mainly contain an organic solvent as the solvent of the conductive ink are preferably used, and solvent-based conductive inks that mainly contain an organic solvent as the solvent of the conductive ink are more preferably used.

In particular, the ink-receiving layer that is included in the conductive-ink-receiving base according to the present invention is preferably used in combination with a conductive ink that particularly contains a polar solvent as the organic solvent because bleeding, a decrease in adhesiveness, etc. that may be caused by the polar solvent can be satisfactorily prevented and it is possible to achieve a fine-line-forming property of such a level that, for example, an increase in the integration density of electronic circuits or the like can be achieved.

Examples of the solvent that can be used in the solvent-based conductive inks include polar solvents such as alcohol solvents, e.g., methanol, ethanol, n-propanol, isopropyl alcohol, n-butanol, isobutyl alcohol, sec-butanol, tert-butanol, heptanol, hexanol, octanol, nonanol, decanol, undecanol, dodecanol, tridecanol, tetradecanol, pentadecanol, stearyl alcohol, ceryl alcohol, cyclohexanol, terpineol, terpineol, and dihydroterpineol; glycol solvents, e.g., 2-ethyl-1,3-hexanediol, ethylene glycol, diethylene glycol, triethylene glycol, polyethylene glycol, propylene glycol, dipropylene glycol, 1,3-butanediol, 1,4-butanediol, and 2,3-butanediol; glycol ether solvents, e.g., ethylene glycol monomethyl ether, ethylene glycol monoethyl ether, ethylene glycol monobutyl ether, diethylene glycol monoethyl ether, diethylene glycol monomethyl ether, diethylene glycol monobutyl ether, ethylene glycol monoethyl ether acetate, ethylene glycol monomethyl ether acetate, ethylene glycol monobutyl ether acetate, diethylene glycol monoethyl ether acetate, diethylene glycol monobutyl ether acetate, diethylene glycol diethyl ether, diethylene glycol dimethyl ether, diethylene glycol dibutyl ether, tetraethylene glycol dimethyl ether, tetraethylene glycol monobutyl ether, propylene glycol monomethyl ether, dipropylene glycol monomethyl ether, tripropylene glycol monomethyl ether, propylene glycol monopropyl ether, dipropylene glycol monopropyl ether, propylene glycol monobutyl ether, dipropylene glycol monobutyl ether, tripropylene glycol monobutyl ether, propylene glycol monomethyl ether acetate, dipropylene glycol monomethyl ether acetate, propylene glycol diacetate, propylene glycol phenyl ether, and dipropylene glycol dimethyl ether; and glycerol.

Among the above polar solvents, a conductive ink that contains a glycol solvent is preferably used in combination with the above-described conductive-ink-receiving layer from the standpoint of preventing bleeding, a decrease in adhesiveness, etc. that may be caused by the glycol solvent and achieving a fine-line-forming property of such a level that, for example, an increase in the integration density of electronic circuits or the like can be achieved.

Among the glycol solvents, in particular, ethylene glycol, diethylene glycol, triethylene glycol, 1,3-butanediol, 1,4-butanediol, 2,3-butanediol, etc. are preferably used.

In the solvent-based conductive ink, ketone solvents such as acetone, cyclohexanone, and methyl ethyl ketone can be used in combination in order to adjust physical properties. In addition, non-polar solvents such as ester solvents, e.g., ethyl acetate, butyl acetate, 3-methoxybutyl acetate, and 3-methoxy-3-methyl-butyl acetate; hydrocarbon solvents such as toluene, in particular, hydrocarbon solvents having 8 or more carbon atoms, e.g., octane, nonane, decane, dodecane, tridecane, tetradecane, cyclooctane, xylene, mesitylene, ethylbenzene, dodecylbenzene, tetralin, trimethylbenzene, and cyclohexane may also be used in combination as required. Furthermore, solvents such as mineral spirits and solvent naphtha, which are mixed solvents, may also be used in combination.

However, an ink-receiving layer formed using the resin composition for forming an ink-receiving layer according to the present invention is particularly preferably used in combination with a conductive ink that contains a polar solvent, and thus the amount of non-polar solvent is preferably 0% to 40% by mass relative to the total amount of solvent contained in the conductive ink.

The same as those exemplified as the aqueous medium (B) can be used as the aqueous medium that can be used as a solvent of the conductive ink. For example, water may be used alone, or a mixed solution of water and a water-soluble solvent may be used. Examples of the water-soluble solvent that can be used include polar solvents such as alcohols, e.g., methyl alcohol, ethyl alcohol, isopropyl alcohol, ethyl carbitol, ethyl cellosolve, and butyl cellosolve; and N-methylpyrrolidone.

The content of the solvent in the conductive ink is preferably in the range of 40% to 90% by mass relative to the total amount of the conductive ink. The content of the polar solvent is preferably in the range of 40% to 100% by mass relative to the total amount of the solvent.

The conductive ink may optionally contain various types of additives in addition to the metal and the solvent.

A dispersing agent can be used as the additive from the standpoint of improving dispersibility of the metal in the solvent.

Examples of the dispersing agent that can be used include amine polymer dispersing agents such as polyethylene imine and polyvinylpyrrolidone; hydrocarbon polymer dispersing agents having carboxylic acid groups in their molecules, such as polyacrylic acid and carboxymethyl cellulose; and polymer dispersing agents having polar groups, such as polyvinyl alcohol, styrene-maleic acid copolymers, olefin-maleic acid copolymers, and copolymers having a polyethyleneimine moiety and a polyethylene oxide moiety in one molecule thereof. Note that the polyvinyl alcohol may be used as a dispersing agent even in the case where a solvent-based conductive ink is used.

Examples of a method for performing printing on the conductive-ink-receiving base or the like with the conductive ink include an ink-jet printing method, a screen printing method, an off-set printing method, a spin coating method, a spray coating method, a bar coating method, a die coating method, a slit coating method, a roll coating method, and a dip coating method.

When a thin line of about 0.01 to 100 which is required for achieving an increase in the integration density of electronic circuits or the like, is printed, among the above methods, an ink-jet printing method is preferably employed.

In the ink-jet printing method, a device that is generally called an ink-jet printer can be used. Specific examples thereof include Konica Minolta EB100, XY100 (manufactured by Konica Minolta IJ Technologies, Inc.) and Dimatix materials printer DMP-3000 and Dimatix materials printer DMP-2831 (manufactured by FUJI FILM Corporation).

Printed matter on which printing is performed on the conductive-ink-receiving base by any of the above methods is preferably baked from the standpoint of providing electrical conductivity by bringing particles of a metal contained in the conductive ink into close contact with each other and joining the particles.

The baking is preferably conducted in the range of about 80° C. to 300° C. for about 2 to 200 minutes. The baking may be conducted in air. Alternatively, from the standpoint of preventing oxidation of the metal, part or all of the baking step may be conducted in a reducing atmosphere.

The baking step can be conducted by using, for example, an oven, a hot-air drying furnace, an infrared drying furnace, or laser irradiation.

On a surface of printed matter obtained through the baking step, a conductive pattern is formed by the metal contained in the conductive ink. This conductive pattern can be used in, for example, a circuit board or an integrated circuit board of an electrical appliance or the like.

In the case where a cross-linked structure is formed by using the cross-linking agent (e2) after printing is conducted with a conductive ink or the like, the cross-linked structure is formed through the baking step after the printing. Thus, durability of printed matter such as a conductive pattern can be improved.

In the case where the cross-linking reaction and the baking step are conducted at the same time, the heating temperature is preferably in the range of about 80° C. to 300° C., more preferably about 100° C. to 300° C., and particularly preferably about 120° C. to 300° C., though the heating temperature varies depending on the type of cross-linking agent (D) used, the combination of cross-linkable functional groups, etc. When the substrate is relatively easily affected by heat, the upper limit of the temperature is preferably 200° C. or lower and more preferably 150° C. or lower.

As described above, printed matter is obtained by performing printing using a conductive ink on, for example, a conductive-ink-receiving base including a conductive ink-receiving layer that is formed by using a resin composition for forming an ink-receiving layer according to the present invention. The printed matter has water resistance of such a level that separation of the conductive ink, disconnection of a conductive pattern, or the like does not occur even when the printed matter is used in a high-temperature or high-humidity environment. In addition, a thin line of such a level that, for example, an increase in the integration density of an electronic circuit or the like is achieved can be formed without causing bleeding.

Accordingly, the printed matter described above can be suitably used in the formation of an electronic circuit using a silver ink or the like, the formation of layers and peripheral wiring that are included in an organic solar cell, an electronic book terminal, an organic EL device, an organic transistor, a flexible printed circuit board, RFID, etc., and the formation of a conducive pattern, more specifically, a circuit board, in producing wiring of an electromagnetic wave shield of a plasma display, for example.

Among conductive patterns produced by the method described above, a conductive pattern produced by performing printing with a conductive ink and then forming a cross-linked structure in the resulting conductive-ink-receiving layer has durability of such a level that a good electrical conduction property can be maintained without causing, for example, dissolution or separation of the conductive-ink-receiving layer even in the case where chemical agents for plating and solvents such as a washing agent adhere to the conductive pattern. Accordingly, the conductive pattern can be suitably used in applications that particularly require durability among the formation of a substrate for forming a circuit using a silver ink or the like, the substrate being used for forming an electronic circuit or an integrated circuit; the formation of layers and peripheral wiring that are included in an organic solar cell, an electronic book terminal, an organic EL device, an organic transistor, a flexible printed circuit board, RFID, etc.; the formation of wiring of an electromagnetic wave shield of a plasma display, etc.

### Examples

The present invention will now be described in detail using Examples.

### Example 1

### Preparation of Resin Composition (I-1) for Forming Ink-Receiving Layer and Preparation of Ink-Receiving Base (II-1) Using the Resin Composition

In a reaction vessel equipped with a stirrer, a reflux condenser, a nitrogen gas-introducing tube, a thermometer, and dropping funnels, 350 parts by mass of deionized water and 4 parts by mass of LATEMUL E-118B (manufactured by Kao Corporation, active ingredient: 25% by mass) were put, and the temperature was increased to 70° C. while blowing nitrogen.

A monomer pre-emulsion was prepared by mixing a vinyl monomer mixture containing 25.0 parts by mass of methyl methacrylate, 45.0 parts by mass of n-butyl acrylate, and 30.0 parts by mass of methacrylic acid, 4 parts by mass of Aquaron KH-1025 (manufactured by Dai-ichi Kogyo Seiyaku Co., Ltd., active ingredient: 25% by mass), and 15 parts by mass of deionized water. Part (5 parts by mass) of this monomer pre-emulsion was added to the reaction vessel under stirring. Subsequently, 0.1 parts by mass of potassium persulfate was added thereto, and polymerization was conducted for 60 minutes while maintaining the temperature in the reaction vessel at 70° C.

Next, the rest (114 parts by mass) of the monomer pre-emulsion and 30 parts by mass of an aqueous solution (active ingredient: 1.0% by mass) of potassium persulfate were respectively added dropwise over a period of 180 minutes using two dropping funnels while maintaining the temperature in the reaction vessel at 70° C. After the completion of the dropwise addition, the resulting mixture was stirred at the same temperature for 60 minutes.

The temperature in the reaction vessel was decreased to 40° C. Subsequently, deionized water was used so that the non-volatile content became 20.0% by mass, and the resulting mixture was then filtered with a 200-mesh filter cloth. Thus, a resin composition (I-1) for forming an ink-receiving layer used in the present invention was prepared.

The resin composition (I-1) for forming an ink-receiving layer prepared as described above was applied onto surfaces of three types of bases represented by (i) to (iii) below using a bar coater so that the dry film thickness became 3 μm. The resulting bases were dried at 70° C. for three minutes using a hot-air dryer. Thus, three types of ink-receiving bases (II-1) each having an ink-receiving layer thereon were prepared.

[Substrates]

(i) PET; polyethylene terephthalate film (manufactured by Toyobo Co., Ltd., Cosmoshine A4300, thickness: 50 μm)

(ii) PI; Polyimide film (manufactured by Du Pont-Toray Co., Ltd., Kapton 200H, thickness 50 μm)

(iii) GL; glass: glass plate, JIS R3202, thickness 2 mm

### Examples 2 to 6 and Examples 8 and 9

### Preparation of Resin Compositions (I-2) to (I-6) and (I-8) and (I-9) for Forming Ink-Receiving Layers and Preparation of Ink-Receiving Bases (II-2) to (II-6) and (II-8) and (II-9) Using the Resin Compositions

Resin compositions (I-2) to (I-6) and (I-8) and (I-9) for forming ink-receiving layers, the resin compositions each having a non-volatile content of 20% by mass, were prepared by the same method as that described in Example 1 except that the composition of the vinyl monomer mixture was changed to the compositions described in Table 1 below.

Ink-receiving bases (II-2) to (II-6) and (II-8) and (II-9) were prepared by the same method as that described in Example 1 except that the resin compositions (I-2) to (I-6) and (I-8) and (I-9) for forming ink-receiving layers were respectively used instead of the resin composition (I-1) for forming an ink-receiving layer.

### Example 7

### Preparation of Resin Composition (I-7) for Forming Ink-Receiving Layer and Preparation of Ink-Receiving Base (II-7) Using the Resin Composition

In a reaction vessel equipped with a stirrer, a reflux condenser, a nitrogen gas-introducing tube, a thermometer, and dropping funnels, 350 parts by mass of deionized water and 4 parts by mass of LATEMUL E-118B (manufactured by Kao Corporation, active ingredient: 25% by mass) were put, and the temperature was increased to 70° C. while blowing nitrogen.

A monomer pre-emulsion was prepared by mixing a vinyl monomer mixture containing 25.0 parts by mass of methyl methacrylate, 45.0 parts by mass of n-butyl acrylate, and 30.0 parts by mass of methacrylic acid, 4 parts by mass of Aquaron KH-1025 (manufactured by Dai-ichi Kogyo Seiyaku Co., Ltd., active ingredient: 25% by mass), and 15 parts by mass of deionized water. Part (5 parts by mass) of this monomer pre-emulsion was added to the reaction vessel under stirring. Subsequently, 0.1 parts by mass of potassium persulfate was added thereto, and polymerization was conducted for 60 minutes while maintaining the temperature in the reaction vessel at 70° C.

Next, the rest (114 parts by mass) of the monomer pre-emulsion and 30 parts by mass of an aqueous solution (active ingredient: 1.0% by mass) of potassium persulfate were respectively added dropwise over a period of 180 minutes using two dropping funnels while maintaining the temperature in the reaction vessel at 70° C. After the completion of the dropwise addition, the resulting mixture was stirred at the same temperature for 60 minutes.

The temperature in the reaction vessel was decreased to 40° C. Subsequently, deionized water was used so that the non-volatile content became 20.0% by mass, and the resulting mixture was then filtered with a 200-mesh filter cloth. Thus, a resin composition (I-7) for forming an ink-receiving layer used in the present invention was prepared.

Next, 100 parts by mass of the above mixture, 0.8 parts by mass (solid content mass ratio 100:3) of a melamine compound [Beckamine M-3 (manufactured by DIC Corporation), non-volatile content: 78%], and deionized water were mixed. Thus, a resin composition (I-7) for forming an ink-receiving layer, the resin composition having a non-volatile content of 20% by mass, was prepared.

The resin composition (I-7) for forming an ink-receiving layer prepared as described above was applied onto surfaces of three types of bases represented by (i) to (iii) below using a bar coater so that the dry film thickness became 3 μm. The resulting bases were dried at 70° C. for three minutes using a hot-air dryer. Thus, three types of ink-receiving bases (II-7) each having an ink-receiving layer thereon were prepared.

### Comparative Example 1

### Preparation of Resin Composition (I′-1) for Forming Ink-Receiving Layer for Comparison and Preparation of Ink-Receiving Base (II′-1) Using the Resin Composition

A 10 mass % aqueous solution of PVA 210 [manufactured by Kuraray Co., Ltd., polyvinyl alcohol having a degree of saponification of 87% to 89% by mole and a degree of polymerization of 1,000] serving as a water-soluble resin was mixed with the resin composition (I-2) for forming an ink-receiving layer prepared in Example 1 at a ratio of resin composition (I-2) for forming ink-receiving layer:PVA 210=300:400 (solid content mass ratio 60:40). Thus, a resin composition (I′-1) for forming an ink-receiving layer, the resin composition having a non-volatile content of 14% by mass, was prepared.

The resin composition (I′-1) for forming an ink-receiving layer prepared as described above was applied onto surfaces of three types of bases represented by (i) to (iii) below using a bar coater so that the dry film thickness became 3 μm. The resulting bases were dried at 70° C. for three minutes using a hot-air dryer. Thus, three types of ink-receiving bases (II′-1) each having an ink-receiving layer thereon were prepared.

### Comparative Example 2

### Preparation of Resin Composition (I′-2) for Forming Conductive-Ink-Receiving Layer for Comparison and Preparation of Conductive Ink-Receiving Base (II′-2) Using the Resin Composition

SNOWTEX O [manufactured by Nissan Chemical Industries, Ltd., colloidal silica, SiO₂ 20 mass % aqueous dispersion] serving as a filler was mixed with the resin composition (I-2) for forming an ink-receiving layer prepared in Example 1 at a ratio of resin composition (I-2) for forming ink-receiving layer:SNOWTEX C=300:200 (solid content mass ratio 60:40). Thus, a resin composition (I′-2) for forming an ink-receiving layer, the resin composition having a non-volatile content of 20% by mass, was prepared.

The resin composition (I′-2) for forming an ink-receiving layer prepared as described above was applied onto surfaces of three types of bases represented by (i) to (iii) below using a bar coater so that the dry film thickness became 3 μm. The resulting bases were dried at 70° C. for three minutes using a hot-air dryer. Thus, three types of ink-receiving bases (II′-2) each having an ink-receiving layer thereon were prepared.

### Comparative Examples 3 and 4

### Preparation of Resin Compositions (I′-3) and (I′-4) for Forming Ink-Receiving Layers and Preparation of Ink-Receiving Bases (II′-3) and (II′-4) Using the Resin Compositions

Resin compositions (I′-3) and (I′-4) for forming ink-receiving layers, the resin compositions each having a non-volatile content of 20% by mass, were prepared by the same method as that described in Example 1 except that the composition of the vinyl monomer mixture was changed to the compositions described in Table 1 below.

Ink-receiving bases (II′-3) and (II′-4) were prepared by the same method as that described in Example 1 except that the resin compositions (I′-3) and (I′-4) for forming ink-receiving layers were respectively used instead of the resin composition (I-1) for forming an ink-receiving layer.

TABLE 1

| | | Example | | | | | | |
|---|---|---|---|---|---|---|---|---|
| | | 1 | 2 | 3 | 4 | 5 | 6 | 7 |
| MMA | Parts by | 25.0 | 15.0 | 5.0 | 35.0 | 2.0 | 15.0 | 25.0 |
| NBMAM | mass | — | 15.0 | 15.0 | 15.0 | 15.0 | 15.0 | — |
| BA | | 45.0 | 40.0 | 40.0 | 35.0 | 38.0 | 39.95 | 45.0 |
| MAA | | 30.0 | 30.0 | 30.0 | 15.0 | 45.0 | 30.0 | 30.0 |
| CHMA | | — | — | 10.0 | — | — | — | — |
| L-SH | | — | — | — | — | — | 0.05 | — |
| Acid value | | 195 | 195 | 195 | 98 | 293 | 195 | 195 |
| Weight-average | | >1,000,000 | >1,000,000 | >1,000,000 | >1,000,000 | >1,000,000 | 700,000 | >1,000,000 |
| molecular weight | | | | | | | | |
| Cross-linking | Parts by | — | — | — | — | — | — | 3.0 |
| agent 1 | mass | | | | | | | |
| Water-soluble | | — | — | — | — | — | — | — |
| resin | | | | | | | | |
| Filler | | — | — | — | — | — | — | — |

| | | | | | | | |
|---|---|---|---|---|---|---|---|
| Component that forms | Not | NBMAM | NBMAM | NBMAM | NBMAM | NBMAM | Cross- |
| cross-linked structure | contained | | | | | | linking |
| | | | | | | | agent 1 |

TABLE 2

| | | Example | | Comparative Example | | | |
|---|---|---|---|---|---|---|---|
| | | 8 | 9 | 1 | 2 | 3 | 4 |
| MMA | Parts by | 25.0 | 20.0 | 25.0 | 25.0 | 19.0 | — |
| NBMAM | mass | — | — | — | — | — | — |
| BA | | — | — | 45.0 | 45.0 | 35.0 | 23.3 |
| MAA | | 30.0 | 30.0 | 30.0 | 30.0 | 30.0 | 76.7 |
| CHMA | | — | — | — | — | — | — |
| EA | | 45.0 | 40.0 | — | — | — | — |
| 2-HEMA | | — | 10.0 | — | — | — | — |
| L-SH | | — | — | — | — | 1.0 | — |
| Acid value | | 195 | 195 | 195 | 195 | 195 | 500 |
| Weight-average | | >1,000,000 | >1,000,000 | >1,000,000 | >1,000,000 | 90,000 | >1,000,000 |
| molecular weight | | | | | | | |
| Cross-linking | Parts by | — | — | — | — | — | — |
| agent 1 | mass | | | | | | |
| Water-soluble | | — | — | 66.7 | — | — | — |
| resin | | | | | | | |
| Filler | | — | — | — | 66.7 | — | — |

| | | | | | | |
|---|---|---|---|---|---|---|
| Component that forms | Not | Not | NBMAM | Not | NBMAM | Not |
| cross-linked structure | contained | contained | | contained | | contained |

Description of abbreviations in Tables 1 and 2

MMA: methyl methacrylate

NBMAM: N-n-butoxymethylacrylamide

BA: n-butyl acrylate

MAA: methacrylic acid

AM: acrylamide

CHMA: cyclohexyl methacrylate

EA: ethyl acrylate

2HEMA: 2-hydroxyethyl methacrylate

L-SH: lauryl mercaptan

Cross-linking agent 1: melamine compound [Beckamine M-3 (manufactured by DIC Corporation), trimethoxymethylmelamine]

Water-soluble resin: PVA 210 [manufactured by Kuraray Co., Ltd., polyvinyl alcohol having a degree of saponification of 87% to 89% by mole and a degree of polymerization of 1,000]

Filler: SNOWTEX O [manufactured by Nissan Chemical Industries, Ltd., colloidal silica, SiO₂ 20% aqueous dispersion]

[Method for measuring acid value]

The acid value of a binder resin is a value calculated on the basis of the amount of acid group-containing vinyl monomer relative to the total amount of vinyl monomers used in the production of the binder resin. The acid value is determined by [the amount (mol) of substance of acid group in acid group-containing vinyl monomer/the total mass of vinyl monomers]×56,100. Specifically, in the case of Example 1, the total amount of vinyl monomers was 100 parts by mass relative to 30 parts by mass of methacrylic acid (molecular weight: 86.09), which has one carboxyl group. Accordingly, the acid value can be calculated to be [{(30/86.09)×1}/100]×56,100=195.

[Method for Measuring Weight-Average Molecular Weight]

A measurement sample was prepared by mixing 80 mg of the binder resin (A) with 20 mL of tetrahydrofuran and stirring the resulting mixed solution for 12 hours. The weight-average molecular weight was measured by gel permeation chromatography (GPC) using the measurement sample. A measuring apparatus and columns described below were used. Measuring apparatus: High-performance GPC apparatus (“HLC-8220 GPC” manufactured by Tosoh Corporation) Columns: The following columns manufactured by Tosoh Corporation were connected in series and used.

“TSKgel G5000” (7.8 mm in internal diameter (I.D.)×30 cm)×1

“TSKgel G4000” (7.8 mm I.D.×30 cm)×1

“TSKgel G3000” (7.8 mm I.D.×30 cm)×1

“TSKgel G2000” (7.8 mm I.D.×30 cm)×1

Detector: RI (differential refractometer)
Column temperature: 40° C.

### Eluent: Tetrahydrofuran

Flow rate: 1.0 mL/min
Amount of injection: 100 μL
Standard sample: A calibration curve was prepared by using standard polystyrenes described below.

### (Standard Polystyrenes)

“TSKgel standard polystyrene A-500” manufactured by Tosoh Corporation

“TSKgel standard polystyrene A-1000” manufactured by Tosoh Corporation

“TSKgel standard polystyrene A-2500” manufactured by Tosoh Corporation

“TSKgel standard polystyrene A-5000” manufactured by Tosoh Corporation

“TSKgel standard polystyrene F-1” manufactured by Tosoh Corporation

“TSKgel standard polystyrene F-2” manufactured by Tosoh Corporation

“TSKgel standard polystyrene F-4” manufactured by Tosoh Corporation

“TSKgel standard polystyrene F-10” manufactured by Tosoh Corporation

“TSKgel standard polystyrene F-20” manufactured by Tosoh Corporation

“TSKgel standard polystyrene F-40” manufactured by Tosoh Corporation

“TSKgel standard polystyrene F-80” manufactured by Tosoh Corporation

“TSKgel standard polystyrene F-128” manufactured by Tosoh Corporation

“TSKgel standard polystyrene F-288” manufactured by Tosoh Corporation

“TSKgel standard polystyrene F-550” manufactured by Tosoh Corporation

In some cases, even after 80 mg of the binder resin (A) was mixed with 20 mL of tetrahydrofuran and the resulting mixed solution was stirred for 12 hours, the binder resin (A) was not completely dissolved, and a residue composed of the binder resin (A) was visually observed when the mixed solution was filtered using a 1-μm membrane filter. In such a case, the binder resin (A) was determined to have a weight-average molecular weight of more than 1,000,000.

[Method for Evaluating Printing Properties]

Printing was performed with solvent-based pigment inks each containing a glycol-based highly polar solvent and a pigment, on a surface of an ink-receiving base prepared by using, as a substrate, the “(i) PET; polyethylene terephthalate film (manufactured by Toyobo Co., Ltd., Cosmoshine A4300, thickness: 50 μm)” in an overlapping manner in the order described below using an ink-jet printer (SP-300V manufactured by Roland DG Corporation). Thus, nine types of printed matter having different color tones and different ink densities were prepared.

[Description of Nine Color Inks]
C(cyan) 100% ink
Y (yellow) 100% ink
M (magenta) 100% ink
Bk (black) 100% ink
Total 200% ink containing C 100% and M 100%
Total 200% ink containing M 100% and Y 100%
Total 200% ink containing Y 100% and C 100%
Total 300% ink containing C 100%, M 100%, and Y 100%
Total 400% ink containing C 100%, M 100%, Y 100%, and K 100%

Printing properties of the printed matter obtained by performing printing with the solvent-based pigment inks were evaluated on the basis of the criteria below.

A; No uneven color, bleeding, cracks, and the like were generated on a printed image formed by using the “total 400% ink”, and a uniform printed image was formed.

B; No uneven color, bleeding, cracks, and the like were generated on a printed image formed by using the “total 300% ink”. However, bleeding and an uneven color were somewhat generated on a printed image obtained by successively performing printing on the above printed image in an overlapping manner using the “total 400% ink”.

C; No uneven color, bleeding, cracks, and the like were generated on a printed image formed by using the “total 200% ink containing C 100% and M 100%”, the “total 200% ink containing M 100% and Y 100%” and the “total 200% ink containing Y 100% and C 100%”. However, bleeding and an uneven color were generated on a printed image obtained by successively performing printing on the above printed image in an overlapping manner using the “total 300% ink”.

D; No uneven color, bleeding, cracks, and the like were generated on a printed image formed by using the “C 100% ink”, the “Y 100% ink”, the “M 100% ink”, and the “Bk 100% ink”. However, bleeding and an uneven color were generated on a printed image obtained by successively performing printing on the above printed image in an overlapping manner using the “total 200% inks”.

E; Bleeding, an uneven color, and cracks were observed on a printed image even in the case where printing was performed using any of the “C 100% ink”, the “Y 100% ink”, the “M 100% ink”, and the “Bk 100% ink”.

Furthermore, printing was performed with water-based pigment inks each containing water and a pigment in an overlapping manner in the order described below using an ink-jet printer (PX-W8000 manufactured by Seiko Epson Corporation) instead of using the ink-jet printer (SP-300V manufactured by Roland DG Corporation) and the solvent-based pigment inks. Thus, ten types of printed matter having different color tones and different ink densities were prepared.

[Description of Ten Color Inks]
C 100% ink
Y 100% ink
M 100% ink
Bk 100% ink
Total 200% ink containing C 100% and M 100%
Total 200% ink containing M 100% and Y 100%
Total 200% ink containing Y 100% and C 100%
Total 300% ink containing C 100%, M 100%, and Y 100%
Total 400% ink containing C 100%, M 100%, Y 100%, and K 100%
Total 500% ink containing C 100%, M 100%, Y 100%, K 100%, and a white 100% ink

Printing properties of printed images obtained by performing printing with the water-based pigment inks were evaluated on the basis of the criteria below.

A; No uneven color, bleeding, cracks, and the like were generated on a printed image formed by using the “total 500% ink containing C 100%, M 100%, Y 100%, K 100%, and the white 100% ink”

B; No uneven color, bleeding, cracks, and the like were generated on a printed image formed by using the “total 400% ink”, and a uniform printed image was formed. However, bleeding and an uneven color were slightly generated on a printed image obtained by successively performing printing on the above printed image in an overlapping manner using the “white 100% ink”.

C; No uneven color, bleeding, cracks, and the like were generated on a printed image formed by using the “total 300% ink”. However, bleeding and an uneven color were slightly generated on a printed image obtained by successively performing printing on the above printed image in an overlapping manner using the “total 400% ink”.

D; No uneven color, bleeding, cracks, and the like were generated on a printed image formed by using the “total 200% ink containing C 100% and M 100%”, the “total 200% ink containing M 100% and Y 100%” and the “total 200% ink containing Y 100% and C 100%”. However, bleeding and an uneven color were generated on a printed image obtained by successively performing printing on the above printed image in an overlapping manner using the “total 300% ink”.

E; No uneven color, bleeding, cracks, and the like were generated on a printed image formed by using the “C 100% ink”, the “Y 100% ink”, the “M 100% ink”, and the “Bk 100% ink”. However, bleeding and an uneven color were generated on a printed image obtained by successively performing printing on the above printed image in an overlapping manner using the “total 200% inks”.

F; Bleeding, an uneven color, and cracks were observed on a printed image even in the case where printing was performed using any of the “C 100% ink”, the “Y 100% ink”, the “M 100% ink”, and the “Bk 100% ink”.

[Method for Evaluating Water Resistance]

A total 400% solid image formed of C100%, M100%, Y100%, and K100% was printed on an ink-receiving base that was prepared by using, as a substrate, the “(i) PET; polyethylene terephthalate film (manufactured by Toyobo Co., Ltd., Cosmoshine A4300, thickness: 50 μm)” with solvent-based pigment inks each containing a glycol-based highly polar solvent and a pigment using an ink-jet printer (SP-300V manufactured by Roland DG Corporation) to prepare printed matter. The printed matter was cut to have a size of 3 cm×3 cm and then immersed in ion exchanged water at 40° C. for 24 hours.

Furthermore, a total 400% solid image formed of C100%, M100%, Y100%, and K100% was printed on an ink-receiving base that was prepared by using, as a substrate, the “(i) PET; polyethylene terephthalate film (manufactured by Toyobo Co., Ltd., Cosmoshine A4300, thickness: 50 μm)” with water-based pigment inks each containing water and a pigment using an ink-jet printer (PX-5002 manufactured by Seiko Epson Corporation) to prepare printed matter. The printed matter was cut to have a size of 3 cm×3 cm and then immersed in ion exchanged water at 40° C. for 24 hours.

After the immersion, the appearance of the ink-receiving base dried at room temperature was visually observed. When no change was observed in the appearance, the printed matter was evaluated as [A]. When whitening was partially slightly observed in the ink-receiving layer or slight part of the ink flowed out into the ion exchanged water, the printed matter was evaluated as [B]. When whitening was observed on substantially the entire surface of the ink-receiving layer or part of the ink flowed out into the ion exchanged water, the printed matter was evaluated as [C]. When part of the ink-receiving layer dissolved and detached from the surface of the substrate or the ink considerably flowed out into the ion exchanged water, the printed matter was evaluated as [D]. When substantially half or more of the ink-receiving layer dissolved and detached from the surface of the substrate or the ink completely flowed out into the ion exchanged water, the printed matter was evaluated as [E].

[Method for Preparing Ink]

[Preparation of Nano-Silver Ink 1 for Ink-Jet Printing]

A solvent-based nano-silver ink 1 for ink-jet printing was prepared by dispersing silver particles having an average particle size of 30 nm in a mixed solvent containing 65 parts by mass of diethylene glycol diethyl ether, 18 parts by mass of γ-butyrolactone, 15 parts by mass of tetraethylene glycol dimethyl ether, and 2 parts by mass of tetraethylene glycol monobutyl ether.

[Preparation of Nano-Silver Ink 2 for Ink-Jet Printing]

A water-based nano-silver ink 2 for ink-jet printing was prepared by dispersing silver particles having an average particle size of 30 nm in a mixed solvent containing 45 parts by mass of ethylene glycol and 55 parts by mass of ion exchanged water.

[Preparation of Nano-Silver Ink 3 for Ink-Jet Printing]

A solvent-based nano-silver ink 3 for ink-jet printing was prepared by dispersing silver particles having an average particle size of 30 nm in tetradecane serving as a solvent.

[Preparation of Silver Paste for Screen Printing]

A silver paste (NPS, manufactured by Harima Chemicals Group, Inc.) was used.

[Printing by Ink-Jet Printing Method]

A straight line having a line width of 100 μm and a film thickness of 0.5 μm was printed on surfaces of the three types of ink-receiving bases obtained by using the substrates (i), (ii), and (iii) so as to have a length of about 1 cm with each of the nano-silver inks 1 to 3 for ink-jet printing using an ink-jet printer (ink-jet testing device EB100 manufactured by Konica Minolta IJ Technologies, Inc., printer head for evaluation: KM512L, the amount of ejection: 42 pL). The ink-receiving bases were then dried at 150° C. for 30 minutes to prepare printed matter (conductive patterns). In the cases where the ink-receiving bases described in Examples 2 to 7 and Comparative Examples 1 to 3 were used, a cross-linked structure was formed in the ink-receiving layers through the drying step at 150° C. for 30 minutes after the printing was performed with the inks. Whether the cross-linked structure was formed or not was determined on the basis of a “gel fraction of a conductive-ink-receiving layer formed by drying at room temperature (23° C.) and then heating at 70° C.” and a “gel fraction of a conductive-ink-receiving layer formed by further heating at 150° C.”, as shown in Tables 3 and 4. Specifically, when the gel fraction of a conductive-ink-receiving layer formed by heating at 150° C. was increased by 25% by mass or more as compared with the gel fraction of a conductive-ink-receiving layer formed by drying at room temperature and then heating at 70° C. (non-cross-linked state), it was determined that a cross-linked structure was formed by high-temperature heating.

Note that the gel fraction can be varied not only by the presence or absence of a cross-linked structure but also by various factors such as a molecular weight of a resin. Therefore, it is not appropriate to determine the presence or absence of the cross-linked structure only on the basis of the magnitude of the value of the gel fraction. However, when the gel fraction after heating was increased by about 25% by mass or more as compared with the gel fraction before heating, a conceivable main factor of the increase in the gel fraction is the formation of a new cross-linked structure by heating. Therefore, in the present invention, the presence or absence of the cross-linked structure was determined on the basis of the change in the gel fraction before and after the heating.

The gel fraction of a conductive-ink-receiving layer formed by drying at room temperature (23° C.) and then heating at 70° C. was calculated by a method described below.

A resin composition for forming a conductive-ink-receiving layer was poured onto a polypropylene film surrounded by thick paper so that a film thickness after drying became 100 μm. The resin composition was dried at a temperature of 23° C. and a humidity of 65% for 24 hours, and then heat-treated at 70° C. for three minutes to form a conductive-ink-receiving layer. The conductive-ink-receiving layer was separated from the polypropylene film and then cut to have a size of 3 cm in length and 3 cm in width. This conductive-ink-receiving layer was used as a test piece. The mass (X) of the test piece 1 was measured, and the test piece 1 was then immersed in 50 mL of methyl ethyl ketone, the temperature of which was adjusted to 25° C., for 24 hours.

A residue (insoluble component) of the test piece 1 that was not dissolved in methyl ethyl ketone by the immersion was filtered with a 300-mesh wire gauze.

The residue obtained as described above was dried at 108° C. for one hour, and the mass (Y) of the dry residue was measured.

Next, a gel fraction was calculated on the basis of a formula [(Y)/(X)]×100 using the values of the masses (X) and (Y).

The “gel fraction of a conductive-ink-receiving layer formed by heating at 150° C.” was calculated by a method described below.

A resin composition for forming a conductive-ink-receiving layer was poured onto a polypropylene film surrounded by thick paper so that a film thickness after drying became 100 μm. The resin composition was dried at a temperature of 23° C. and a humidity of 65% for 24 hours, and then dried by heating at 150° C. for 30 minutes to form a conductive-ink-receiving layer. The conductive-ink-receiving layer was separated from the polypropylene film and then cut to have a size of 3 cm in length and 3 cm in width. This conductive-ink-receiving layer was used as a test piece 2. The mass (X′) of the test piece 2 was measured, and the test piece 2 was then immersed in 50 mL of methyl ethyl ketone, the temperature of which was adjusted to 25° C., for 24 hours.

A residue (insoluble component) of the test piece 2 that was not dissolved in methyl ethyl ketone by the immersion was filtered with a 300-mesh wire gauze.

The residue obtained as described above was dried at 108° C. for one hour, and the mass (Y′) of the dry residue was measured.

Next, a gel fraction was calculated on the basis of a formula [(Y′)/(X′)]×100 using the values of the masses (X′) and (Y′).

[Printing by Screen Printing Method]

A straight line having a line width of 50 μm and a film thickness of 1 μm was printed on surfaces of the three types of ink-receiving bases obtained by using the substrates (i), (ii), and (iii) so as to have a length of about 1 cm with the silver paste for screen printing using a metal-mesh 250 screen printing plate. The ink-receiving bases were then dried at 150° C. for 30 minutes to prepare printed matter (conductive patterns).

Regarding the conductive-ink-receiving bases described in Examples 2 to 7 and Comparative Examples 1 to 3, a cross-linked structure was formed in the ink-receiving layers through the drying step at 150° C. for 30 minutes after the printing was performed with the ink. The presence or absence of the cross-lined structure was determined by the same method as that described above.

[Method for Evaluating Fine-Line-Forming Property]

The entire printed portion (line portion) formed on the surface of the printed matter (conductive pattern) prepared by the method described above was observed with an optical microscope (digital microscope VHX-100, manufactured by Keyence Corporation) to check the presence or absence of bleeding of the printed portion.

Specifically, when no bleeding was observed in the outer edge of the printed portion (line portion), the boundary between the printed portion and the non-printed portion was clear, and there was no difference in height between the outer edge and a central portion of the line portion and the line portion was flat and smooth as a whole, the printed matter was evaluated as “A”. When bleeding was somewhat observed in a small portion of the outer edge of the printed portion (line portion), but the boundary between the printed portion and the non-printed portion was clear and the line portion was flat and smooth as a whole, the printed matter was evaluated as “B”. When bleeding was somewhat observed within a region of about ⅓ of the outer edge of the printed portion (line portion) and the boundary between the printed portion and the non-printed portion was partially unclear in the bleeding portion, but the line portion was flat and smooth as a whole and at such a level that the line portion could be used, the printed matter was evaluated as “C”. When bleeding was observed within a region of about ⅓ to ½ of the outer edge of the printed portion (line portion), the boundary between the printed portion and the non-printed portion was partially unclear in the bleeding portion, and the outer edge and a central portion of the line portion were not flat and smooth, the printed matter was evaluated as “D”. When bleeding was observed in a region of about ½ or more of the outer edge of the printed portion (line portion), the boundary between the printed portion and the non-printed portion was partially unclear in the bleeding portion, and the outer edge and a central portion of the line portion were not flat and smooth, the printed matter was evaluated as “E”.

[Method for Evaluating Durability]

A rectangular region (area) having a length of 3 cm and a width of 1 cm was printed on a surface of an ink-receiving base obtained by using the substrate (ii) so as to have a film thickness of 0.5 μm with the nano-silver ink 1 for ink-jet printing using an ink-jet printer (ink-jet testing device EB100 manufactured by Konica Minolta IJ Technologies, Inc., printer head for evaluation: KM512L, the amount of ejection: 42 pL). The ink-receiving base was then dried at 150° C. for 30 minutes to prepare printed matter (conductive pattern). Regarding the conductive-ink-receiving bases described in Examples 2 to 7 and Comparative Examples 1 to 3, a cross-linked structure was formed in the ink-receiving layers through the drying step at 150° C. for 30 minutes after the printing was performed with the ink.

The printed matter (conductive pattern) was cut to have a size of 3 cm×3 cm so that both the printed portion and the non-printed portion of the ink-receiving layer could be observed. The printed matter was immersed in a 5 mass % aqueous hydrochloric acid solution or a 5 mass % aqueous sodium hydroxide solution, the temperature of which was adjusted to 40° C., for 24 hours. The appearance of the printed matter after the immersion was observed. Specifically, after the immersion, the appearances of the printed portion and ink-receiving layer of the printed matter dried at room temperature were visually observed. When no change was observed in the appearances, the printed matter was evaluated as W. When no change was observed in the printed portion, but whitening was slightly partially observed in the ink-receiving layer at such a level that the printed matter could be used in practical applications, the printed matter was evaluated as [B]. When no change was observed in the printed portion, but whitening was observed on substantially the entire surface of the ink-receiving layer, the printed matter was evaluated as [C]. When part of the ink-receiving layer dissolved and part of the printed portion or the ink-receiving layer detached from the surface of the substrate, the printed matter was evaluated as [D]. When substantially half or more of the ink-receiving layer dissolved and half or more of the printed portion or ink-receiving layer detached from the surface of the substrate, the printed matter was evaluated as [E].

[Method for Evaluating Electrical Conduction Property]

A rectangular region (area) having a length of 3 cm and a width of 1 cm was printed on surfaces of two types of conductive-ink-receiving bases obtained by using the substrates (i) and (ii) so as to have a film thickness of 0.5 μm with the nano-silver ink 1 for ink-jet printing using an ink-jet printer (ink-jet testing device EB100 manufactured by Konica Minolta IJ Technologies, Inc., printer head for evaluation: KM512L, the amount of ejection: 42 pL). The conductive-ink-receiving bases were then dried at 150° C. for 30 minutes to prepare printed matter (conductive patterns). Regarding the conductive-ink-receiving bases described in Examples 2 to 7 and Comparative Examples 1 to 3, a cross-linked structure was formed in the ink-receiving layers through the drying step at 150° C. for 30 minutes after the printing was performed with the ink.

Furthermore, a rectangular region (area) having a length of 3 cm and a width of 1 cm was printed on surfaces of two types of conductive-ink-receiving bases obtained by using the substrates (i) and (ii) so as to have a film thickness of 1 μm using the silver paste for screen printing with a metal-mesh 250 screen printing plate. The conductive-ink-receiving bases were then dried at 150° C. for 30 minutes to prepare printed matter (conductive patterns).

The volume resistivity of a solid printed portion of the rectangular region having a length of 3 cm and a width of 1 cm and formed on the surface of the printed matter (conductive pattern) obtained by the method described above was measured using a LORESTA resistivity meter (MCP-T610 manufactured by Mitsubishi Chemical Corporation). Printed matter having a volume resistivity of less than 5×10⁻⁶ Ω·cm was evaluated as “A”. Printed matter which had a volume resistivity of 5×10⁻⁶ Ω·cm or more and less than 9×10⁻⁶ Ω·cm and which was at such a level that the printed matter could be satisfactorily used was evaluated as “B”. Printed matter which had a volume resistivity of 9×10⁻⁶ Ω·cm or more and less than 5×10⁻⁵ Ω·cm and which was at such a level that the printed matter could be used was evaluated as “C”. Printed matter having a volume resistivity of 5×10⁻⁵ Ω·cm or more and less than 9×10⁻⁵ Ω·cm was evaluated as “D”. Printed matter which had a volume resistivity of 9×10⁻⁵ Ω·cm or more and which was difficult to be used in practical applications was evaluated as “E”.

[Method for Evaluating Adhesiveness Between Substrate and Ink-Receiving Layer]

A cellophane adhesive tape (CT405AP-24 manufactured by Nichiban Co., Ltd., 24 mm) was applied onto a surface (onto an ink-receiving layer) of each of the ink-receiving bases by pressing with a finger before printing was conducted. The cellophane adhesive tape was then peeled off in a direction at an angle of 90 degrees with respect to the surface of the conductive-ink-receiving base. The adhesive surface of the peeled cellophane adhesive tape was visually observed. The adhesiveness was evaluated on the basis of the presence or absence of a substance adhering to the adhesive surface of the tape.

An ink-receiving base in which no ink-receiving layer adhered to the adhesive surface of the peeled cellophane adhesive tape was evaluated as “A”. An ink-receiving base in which less than about 5% of the area of the ink-receiving layer relative to the adhering area of the adhesive tape was detached from the substrate and adhered to the adhesive tape was evaluated as “B”. An ink-receiving base in which about 5% or more and less than 50% of the area of the ink-receiving layer relative to the adhering area of the adhesive tape was detached from the substrate and adhered to the adhesive tape was evaluated as “C”. An ink-receiving base in which about 50% or more of the area of the ink-receiving layer relative to the adhering area of the adhesive tape was detached from the substrate and adhered to the adhesive tape was evaluated as “D”.

TABLE 3

| | Example | | | | | | |
|---|---|---|---|---|---|---|---|
| | 1 | 2 | 3 | 4 | 5 | 6 | 7 |
| Gel fraction | 66 | 65 | 70 | 72 | 60 | 50 | 45 |
| (After drying at 70° C.; mass %) | | | | | | | |
| Gel fraction | 70 | 100 | 100 | 99 | 100 | 98 | 97 |
| (After drying at 150° C.; | | | | | | | |
| mass %) | | | | | | | |

TABLE 4

| | Example | | Comparative Example | | | |
|---|---|---|---|---|---|---|
| | 8 | 9 | 1 | 2 | 3 | 4 |
| Gel fraction | 76 | 80 | 47 | 53 | 20 | 40 |
| (After drying at 70° C.; mass %) | | | | | | |
| Gel fraction | 81 | 85 | 73 | 78 | 24 | 45 |
| (After drying at 150° C.; mass %) | | | | | | |

TABLE 5

| | | | Example | | | | |
|---|---|---|---|---|---|---|---|
| | | | 1 | 2 | 3 | 4 | 5 |
| Printing | Solvent-based pigment ink | PET | A | B | B | A | B |
| properties | Water-based pigment ink | PET | B | B | B | C | B |
| Water | Solvent-based pigment ink | PET | A | A | B | A | B |
| resistance | Water-based pigment ink | PET | A | A | A | A | A |
| Fine-line- | Solvent-based nano-silver | PET | A | A | B | A | B |
| forming | ink 1 for ink-jet printing | PI | A | A | B | A | B |
| property | Water-based nano-silver | PET | A | A | C | B | A |
| | ink 2 for ink-jet printing | PI | A | A | C | B | A |
| | Solvent-based nano-silver | PET | B | B | B | B | B |
| | ink 3 for ink-jet printing | PI | B | B | B | B | B |
| | Silver paste for screen | PET | A | A | B | B | B |
| | printing | PI | A | A | B | B | B |
| Durability | 5 mass % Aqueous | PI | E | A | B | A | A |
| | hydrochloric acid solution | | | | | | |
| | 5 mass % Aqueous sodium | PI | E | A | B | A | A |
| | hydroxide solution | | | | | | |
| Electrical | Solvent-based nano-silver | PET | A | A | B | A | B |
| conduction | ink 1 for ink-jet printing | PI | A | A | B | A | B |
| | Silver paste for screen | PET | A | A | B | B | B |
| property | printing | PI | A | A | B | B | B |

| | | | | | | |
|---|---|---|---|---|---|---|
| Adhesiveness | PET | A | A | A | A | A |
| | PI | B | A | A | A | A |
| | GL | B | A | A | A | A |

TABLE 6

| | | | Example | | | |
|---|---|---|---|---|---|---|
| | | | 6 | 7 | 8 | 9 |
| Printing | Solvent-based pigment ink | PET | B | A | A | A |
| properties | Water-based pigment ink | PET | B | B | A | A |
| Water resistance | Solvent-based pigment ink | PET | B | A | B | B |
| | Water-based pigment ink | PET | A | A | A | A |
| Fine-line-forming | Solvent-based nano-silver | PET | B | A | A | A |
| property | ink 1 for ink-jet printing | PI | B | A | A | A |
| | Water-based nano-silver | PET | A | B | A | A |
| | ink 2 for ink-jet printing | PI | A | B | A | A |
| | Solvent-based nano-silver | PET | B | C | B | B |
| | ink 3 for ink-jet printing | PI | B | C | B | B |
| | Silver paste for screen | PET | B | B | A | A |
| | printing | PI | B | B | A | A |
| Durability | 5 mass % Aqueous | PI | B | A | E | E |
| | hydrochloric acid solution | | | | | |
| | 5 mass % Aqueous sodium | PI | B | A | E | E |
| | hydroxide solution | | | | | |
| Electrical | Solvent-based nano-silver | PET | B | A | A | A |
| conduction | ink 1 for ink-jet printing | PI | B | A | A | A |
| property | Silver paste for screen | PET | B | B | A | A |
| | printing | PI | B | B | A | A |

| | | | | | |
|---|---|---|---|---|---|
| Adhesiveness | PET | A | A | A | A |
| | PI | A | A | B | B |
| | GL | A | A | B | B |

TABLE 7

| | | | Comparative | | | |
|---|---|---|---|---|---|---|
| | | | Example | | | |
| | | | 1 | 2 | 3 | 4 |
| Printing | Solvent-based pigment ink | PET | E | E | E | E |
| properties | Water-based pigment ink | PET | B | F | D | F |
| Water resistance | Solvent-based pigment ink | PET | E | E | E | E |
| | Water-based pigment ink | PET | E | E | C | E |
| Fine-line-forming | Solvent-based nano-silver | PET | E | E | E | E |
| property | ink 1 for ink-jet printing | PI | E | E | E | E |
| | Water-based nano-silver | PET | C | E | E | E |
| | ink 2 for ink-jet printing | PI | C | E | E | E |
| | Solvent-based nano-silver | PET | E | E | E | E |
| | ink 3 for ink-jet printing | PI | E | E | E | E |
| | Silver paste for screen | PET | E | E | E | E |
| | printing | PI | E | E | E | E |
| Durability | 5 mass % Aqueous | PI | E | E | E | E |
| | hydrochloric acid solution | | | | | |
| | 5 mass % Aqueous sodium | PI | E | E | E | E |
| | hydroxide solution | | | | | |
| Electrical | Solvent-based nano-silver | PET | E | E | E | E |
| conduction | ink 1 for ink-jet printing | PI | E | E | E | E |
| property | Silver paste for screen | PET | E | E | E | E |
| | printing | PI | E | E | E | E |

| | | | | | |
|---|---|---|---|---|---|
| Adhesiveness | PET | D | D | C | D |
| | PI | D | D | C | D |
| | GL | D | D | C | D |

The printed matter obtained in Example 1 did not cause bleeding or the like and had excellent water resistance and good adhesiveness. The printed matter obtained in Examples 2, 3, 5, 6, and 7 did not cause bleeding or the like and had excellent water resistance and excellent adhesiveness. The printed matter obtained in Example 4 somewhat caused bleeding or the like when printing was conducted with the water-based pigment ink, but the bleeding or the like was at such a level that the printed matter could be used in practical applications. The printed matter obtained in Example 4 had excellent water resistance and excellent adhesiveness. The printed matter obtained in Examples 8 and 9 had excellent printing properties particularly to the water-based pigment ink.

In contrast, the printed matter of Comparative Example 1 obtained by using a receiving layer containing polyvinyl alcohol, which is a water-soluble resin, had excellent printing properties to the water-based pigment ink. However, when printing was conducted with the solvent-based pigment ink, significant bleeding or the like was caused. Regarding the printed matter of Comparative Example 2, which was obtained by using a receiving layer containing a filler, the printed matter of Comparative Example 3, which was obtained by using, as a resin that forms a receiving layer, a resin having a weight-average molecular weight of less than 100,000, and the printed matter of Comparative Example 4, which was obtained by using a resin having an acid value out of the predetermined range, bleeding or the like was caused in both the case where printing was conducted using the solvent-based pigment ink and the case where printing was conducted using the water-based pigment ink, and adhesiveness to the bases was also not sufficient.

The conductive patterns obtained in Examples 1, 8, and 9 had excellent fine-line-forming properties and excellent electrical conduction properties of the patterns. The conductive pattern obtained in Example 2 had an excellent fine-line-forming property and an excellent electrical conduction property of the pattern, and excellent durability. The conductive pattern obtained in Example 3 had a good fine-line-forming property, a good electrical conduction property, and good durability. The conductive patterns obtained in Examples 4 and 5 had excellent durability, and good fine-line-forming properties and a good electrical conduction property. The conductive pattern obtained in Example 6 had a good fine-line-forming property, a good electrical conduction property, and good durability. The conductive pattern obtained in Example 7 caused a slight decrease in the fine-line-forming property in some types of nano-silver ink, but had excellent durability, an excellent electrical conduction property, and a good fine-line-forming property.

In contrast, the conductive patterns obtained in Comparative Examples 1 to 4 had an insufficient fine-line-forming property, insufficient durability, and an insufficient electrical conduction property in terms of practical applications. Thus, the conductive patterns obtained in Comparative Examples 1 to 4 were difficult to be used in electric circuits or the like.

1. A resin composition comprising:
a binder resin (A) having a weight-average molecular weight of 100,000 or more and an acid value of 90 to 450;
an aqueous medium (B); and
as required, at least one component (C) selected from the group consisting of a water-soluble resin (c1) and an inorganic filler (c2),
wherein the binder resin (A) is dispersed in the aqueous medium (B), and the content of the at least one component (C) relative to the total amount of the binder resin (A) is 0% to 15% by mass.

2. The resin composition according claim 1, wherein the binder resin (A) is a vinyl resin (A1).

3. The resin composition according to claim 2, wherein the vinyl resin (A1) is obtained by polymerizing a vinyl monomer mixture, and as required, performing neutralization, wherein the vinyl monomer mixture contains 6% to 70% by mass of a vinyl monomer having an acid group, 0.01% to 80% by mass of methyl methacrylate, and a total 5% to 60% by mass of at least one selected from the group consisting of a hydroxyalkyl (meth)acrylate and a (meth)acrylic acid alkyl ester having an alkyl group having 2 to 12 carbon atoms relative to the total amount of the vinyl monomer mixture.

4. The resin composition according to claim 3, wherein hydroxyalkyl (meth)acrylate is selected from the group consisting of 2-hydroxyethyl (meth)acrylate, 2-hydroxypropyl (meth)acrylate, 2-hydroxybutyl (meth)acrylate, and 4-hydroxybutyl (meth)acrylate.

5. The resin composition for forming an ink receiving layer according to claim 2, wherein the vinyl resin (A1) has a cross-linkable functional group.

6. The resin composition according to claim 5, wherein the cross-linkable functional group is at least one thermally cross-linkable functional group selected from the group consisting of a methylolamide group and an alkoxymethylamide group.

7. The resin composition according to claim 1, further comprising a cross-linking agent (D), wherein the cross-linking agent (D) undergoes a cross-linking reaction when heated to 100° C. or higher.

8. The resin composition according to claim 7, wherein the cross-linking agent (D) is at least one thermal cross-linking agent (d1-2) selected from the group consisting of a melamine compound, an epoxy compound, a blocked isocyanate compound, an oxazoline compound, and a carbodiimide compound.

9. An ink-receiving base comprising a substrate and an ink-receiving layer disposed on part or the entirety of a surface of the substrate, the ink-receiving layer being formed by using the resin composition according to claim 1.

10. Printed matter produced by performing printing with an ink on the ink-receiving layer of the ink-receiving base according to claim 9.

11. The printed matter according to claim 10, wherein the ink is a pigment ink that contains a pigment or a conductive ink that contains a conductive substance.

12. A conductive pattern produced by performing printing with a condutive ink on the ink-receiving layer of the ink-receiving base according to claim 9.

13. A conductive pattern produced by performing printing with a conductive ink on the ink-receiving base according to claim 9, and then forming a cross-linked structure in an ink-receiving layer on which the printing has been performed.

14. An electric circuit comprising the conductive pattern according to claim 12.

15. A method for producing printed matter comprising:
applying the resin composition according to claim 5 onto part or the entirety of a surface of a substrate;
forming an ink-receiving layer by performing drying under a condition in which the resin composition does not undergo a cross-linking reaction;
performing printing on a surface of the ink-receiving layer with an ink; and
then forming a cross-linked structure by heating the ink-receiving layer on which the printing has been performed to cause a cross-linking reaction.

16. The resin composition according to claim 3, wherein the (meth)acrylic acid alkyl ester is ethyl (meth)acrylate.

17. The resin composition according to claim 5, further comprising a cross-linking agent (D), wherein the cross-linking agent (D) undergoes a cross-linking reaction by being heated to 100° C. or higher.

18. An electric circuit comprising the conductive pattern according to claim 13.
